(19) United States
(12) Patent Application Publication
(10) Pub. No.: US 2026/0111627 A1
(43) Pub. Date: Apr. 23, 2026

(54) SIMULATED SMART PEDESTRIANS

(71) Applicant: MOTIONAL AD LLC, Boston, MA (US)

(72) Inventors: Nicholas Britten, Boston, MA (US); Vaidehi Kishor Patil, Boston, MA (US); Avram Block, Boston, MA (US); Paul Schmitt, Boston, MA (US)

(21) Appl. No.: 19/120,476

(22) PCT Filed: Oct. 13, 2023
(86) PCT No.: PCT/US2023/035149

§ 371 Date: Apr. 11, 2025

Related U.S. Application Data
(60) Provisional application No. 63/416,484, filed on Oct. 14, 2022.

(51) Int. Cl. G06F 30/20

(52) U.S. Cl. CPC G06F 30/20

(57) ABSTRACT

Provided are methods for simulated smart pedestrians, The method includes obtaining attributes of at least one pedestrian dynamics model. Simulated sensor data associated with the environment is generated. Operation of an autonomous system in the environment is simulated based on the simulated sensor data, wherein vehicle-pedestrian interactions are modeled by the at least one pedestrian dynamics model as external forces in the environment impacting behavior of the respective pedestrian.

### CROSS-REFERENCE TO RELATED APPLICATIONS

This application claims priority to U.S. Provisional Patent Application No. 63/416,484, filed Oct. 14, 2022 entitled “Simulated Smart Pedestrians,” the entirety of which is incorporated by reference herein.

### BACKGROUND

Autonomous systems obtain data from the surrounding environment and use the data to navigate through the environment. The autonomous systems include subsystems, sensors, and devices that process the data to enable the autonomous system to recognize and understand the environment. Based on the output of the subsystems, sensors, and devices, the autonomous systems make decisions to navigate through the environment.

### BRIEF DESCRIPTION OF THE FIGURES

FIG. 1 is an example environment in which a vehicle including one or more components of an autonomous system can be implemented;

FIG. 2 is a diagram of one or more systems of a vehicle including an autonomous system;

FIG. 3 is a diagram of components of one or more devices and/or one or more systems of FIGS. 1 and 2;

FIG. 4 is a diagram of certain components of an autonomous system;

FIG. 5 shows a diagram of an implementation of a process for simulated smart pedestrians;

FIG. 6 shows a simulation infrastructure;

FIG. 7A is an illustration of a social force model;

FIG. 7B is an illustration of pedestrians moving through an environment subject to external forces;

FIG. 8A shows varying zones in which the zone of influence is classified;

FIG. 8B shows proactive metrics associated with safety assessment of simulations including pedestrian dynamics models based on social force models;

FIG. 9 shows a simulation of smart pedestrians according to a social force model in varying scenarios;

FIG. 10 shows a flowchart of a first process for simulated smart pedestrians; and

FIG. 11 shows a flowchart of a second process for simulated smart pedestrians.

### DETAILED DESCRIPTION

In the following description numerous specific details are set forth in order to provide a thorough understanding of the present disclosure for the purposes of explanation. It will be apparent, however, that the embodiments described by the present disclosure can be practiced without these specific details. In some instances, well-known structures and devices are illustrated in block diagram form in order to avoid unnecessarily obscuring aspects of the present disclosure.

Specific arrangements or orderings of schematic elements, such as those representing systems, devices, modules, instruction blocks, data elements, and/or the like are illustrated in the drawings for ease of description. However, it will be understood by those skilled in the art that the specific ordering or arrangement of the schematic elements in the drawings is not meant to imply that a particular order or sequence of processing, or separation of processes, is required unless explicitly described as such. Further, the inclusion of a schematic element in a drawing is not meant to imply that such element is required in all embodiments or that the features represented by such element may not be included in or combined with other elements in some embodiments unless explicitly described as such.

Further, where connecting elements such as solid or dashed lines or arrows are used in the drawings to illustrate a connection, relationship, or association between or among two or more other schematic elements, the absence of any such connecting elements is not meant to imply that no connection, relationship, or association can exist. In other words, some connections, relationships, or associations between elements are not illustrated in the drawings so as not to obscure the disclosure. In addition, for ease of illustration, a single connecting element can be used to represent multiple connections, relationships or associations between elements. For example, where a connecting element represents communication of signals, data, or instructions (e.g., “software instructions”), it should be understood by those skilled in the art that such element can represent one or multiple signal paths (e.g., a bus), as may be needed, to affect the communication.

Although the terms first, second, third, and/or the like are used to describe various elements, these elements should not be limited by these terms. The terms first, second, third, and/or the like are used only to distinguish one element from another. For example, a first contact could be termed a second contact and, similarly, a second contact could be termed a first contact without departing from the scope of the described embodiments. The first contact and the second contact are both contacts, but they are not the same contact.

The terminology used in the description of the various described embodiments herein is included for the purpose of describing particular embodiments only and is not intended to be limiting. As used in the description of the various described embodiments and the appended claims, the singular forms “a,” “an” and “the” are intended to include the plural forms as well and can be used interchangeably with “one or more” or “at least one,” unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this description specify the presence of stated features, integers, steps, operations, elements, and/or components, but do not preclude the presence or addition of one or more other features, integers, steps, operations, elements, components, and/or groups thereof.

As used herein, the terms “communication” and “communicate” refer to at least one of the reception, receipt, transmission, transfer, provision, and/or the like of information (or information represented by, for example, data, signals, messages, instructions, commands, and/or the like). For one unit (e.g., a device, a system, a component of a device or system, combinations thereof, and/or the like) to be in communication with another unit means that the one unit is able to directly or indirectly receive information from and/or send (e.g., transmit) information to the other unit. This may refer to a direct or indirect connection that is wired and/or wireless in nature. Additionally, two units may be in communication with each other even though the information transmitted may be modified, processed, relayed, and/or routed between the first and second unit. For example, a first unit may be in communication with a second unit even though the first unit passively receives information and does not actively transmit information to the second unit. As another example, a first unit may be in communication with a second unit if at least one intermediary unit (e.g., a third unit located between the first unit and the second unit) processes information received from the first unit and transmits the processed information to the second unit. In some embodiments, a message may refer to a network packet (e.g., a data packet and/or the like) that includes data.

As used herein, the term “if” is, optionally, construed to mean “when”, “upon”, “in response to determining,” “in response to detecting,” and/or the like, depending on the context. Similarly, the phrase “if it is determined” or “if [a stated condition or event] is detected” is, optionally, construed to mean “upon determining,” “in response to determining,” “upon detecting [the stated condition or event],” “in response to detecting [the stated condition or event],” and/or the like, depending on the context. Also, as used herein, the terms “has”, “have”, “having”, or the like are intended to be open-ended terms. Further, the phrase “based on” is intended to mean “based at least partially on” unless explicitly stated otherwise.

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments can be practiced without these specific details. In other instances, well-known methods, procedures, components, circuits, and networks have not been described in detail so as not to unnecessarily obscure aspects of the embodiments.

### General Overview

In some aspects and/or embodiments, systems, methods, and computer program products described herein include and/or implement simulated smart pedestrians. Pedestrian behavior is modeled as being impacted by one or more forces. A simulation is executed including the smart pedestrians. In examples, the simulation enables testing, validation, and verification of autonomous system performance based on simulated vehicle-pedestrian interactions.

By virtue of the implementation of systems, methods, and computer program products described herein, techniques for simulated smart pedestrians enables trialing, evaluating, and iterating vehicle behavior solutions. Complex scenarios are replicated during simulation without causing danger to humans while enabling development of autonomous vehicles evaluated during conflicts with humans.

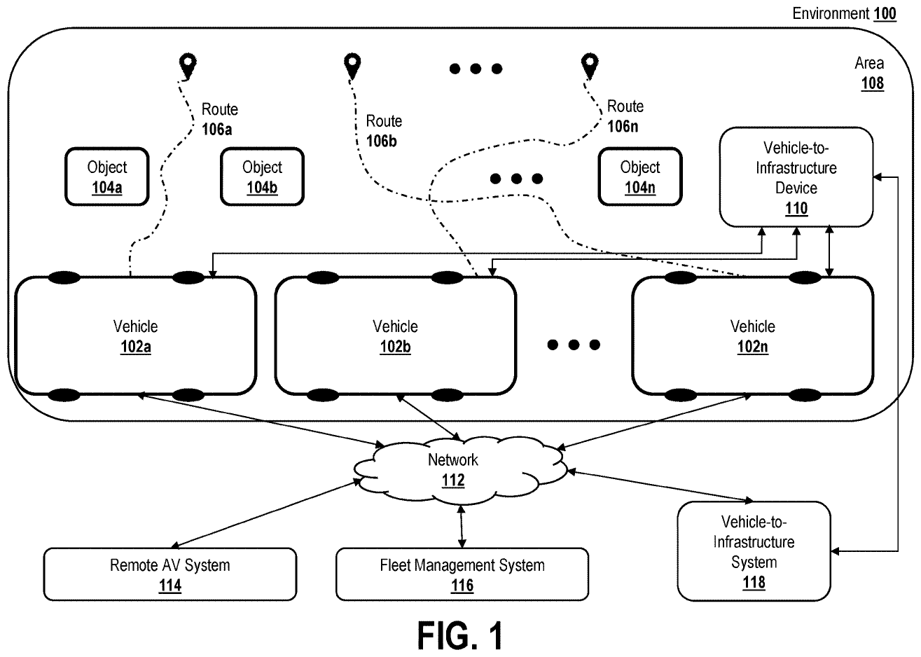

Referring now to FIG. 1, illustrated is example environment 100 in which vehicles that include autonomous systems, as well as vehicles that do not, are operated. As illustrated, environment 100 includes vehicles 102a-102n, objects 104a-104n, routes 106a-106n, area 108, vehicle-to-infrastructure (V2I) device 110, network 112, remote autonomous vehicle (AV) system 114, fleet management system 116, and V2I system 118. Vehicles 102a-102n, vehicle-to-infrastructure (V2I) device 110, network 112, autonomous vehicle (AV) system 114, fleet management system 116, and V2I system 118 interconnect (e.g., establish a connection to communicate and/or the like) via wired connections, wireless connections, or a combination of wired or wireless connections. In some embodiments, objects 104a-104n interconnect with at least one of vehicles 102a-102n, vehicle-to-infrastructure (V2I) device 110, network 112, autonomous vehicle (AV) system 114, fleet management system 116, and V2I system 118 via wired connections, wireless connections, or a combination of wired or wireless connections.

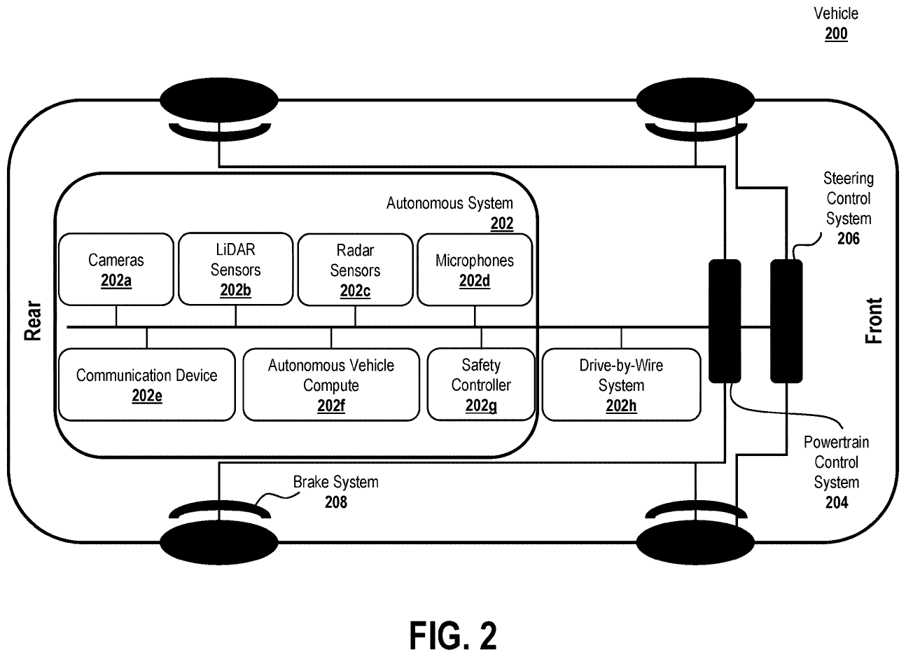

Vehicles 102a-102n (referred to individually as vehicle 102 and collectively as vehicles 102) include at least one device configured to transport goods and/or people. In some embodiments, vehicles 102 are configured to be in communication with V2I device 110, remote AV system 114, fleet management system 116, and/or V2I system 118 via network 112. In some embodiments, vehicles 102 include cars, buses, trucks, trains, and/or the like. In some embodiments, vehicles 102 are the same as, or similar to, vehicles 200, described herein (see FIG. 2). In some embodiments, a vehicle 200 of a set of vehicles 200 is associated with an autonomous fleet manager. In some embodiments, vehicles 102 travel along respective routes 106a-106n (referred to individually as route 106 and collectively as routes 106), as described herein. In some embodiments, one or more vehicles 102 include an autonomous system (e.g., an autonomous system that is the same as or similar to autonomous system 202).

Objects 104a-104n (referred to individually as object 104 and collectively as objects 104) include, for example, at least one vehicle, at least one pedestrian, at least one cyclist, at least one structure (e.g., a building, a sign, a fire hydrant, etc.), and/or the like. Each object 104 is stationary (e.g., located at a fixed location for a period of time) or mobile (e.g., having a velocity and associated with at least one trajectory). In some embodiments, objects 104 are associated with corresponding locations in area 108.

Routes 106a-106n (referred to individually as route 106 and collectively as routes 106) are each associated with (e.g., prescribe) a sequence of actions (also known as a trajectory) connecting states along which an AV can navigate. Each route 106 starts at an initial state (e.g., a state that corresponds to a first spatiotemporal location, velocity, and/or the like) and ends at a final goal state (e.g., a state that corresponds to a second spatiotemporal location that is different from the first spatiotemporal location) or goal region (e.g. a subspace of acceptable states (e.g., terminal states)). In some embodiments, the first state includes a location at which an individual or individuals are to be picked-up by the AV and the second state or region includes a location or locations at which the individual or individuals picked-up by the AV are to be dropped-off. In some embodiments, routes 106 include a plurality of acceptable state sequences (e.g., a plurality of spatiotemporal location sequences), the plurality of state sequences associated with (e.g., defining) a plurality of trajectories. In an example, routes 106 include only high level actions or imprecise state locations, such as a series of connected roads dictating turning directions at roadway intersections. Additionally, or alternatively, routes 106 may include more precise actions or states such as, for example, specific target lanes or precise locations within the lane areas and targeted speed at those positions. In an example, routes 106 include a plurality of precise state sequences along the at least one high level action sequence with a limited lookahead horizon to reach intermediate goals, where the combination of successive iterations of limited horizon state sequences cumulatively correspond to a plurality of trajectories that collectively form the high level route to terminate at the final goal state or region.

Area 108 includes a physical area (e.g., a geographic region) within which vehicles 102 can navigate. In an example, area 108 includes at least one state (e.g., a country, a province, an individual state of a plurality of states included in a country, etc.), at least one portion of a state, at least one city, at least one portion of a city, etc. In some embodiments, area 108 includes at least one named thoroughfare (referred to herein as a “road”) such as a highway, an interstate highway, a parkway, a city street, etc. Additionally, or alternatively, in some examples area 108 includes at least one unnamed road such as a driveway, a section of a parking lot, a section of a vacant and/or undeveloped lot, a dirt path, etc. In some embodiments, a road includes at least one lane (e.g., a portion of the road that can be traversed by vehicles 102). In an example, a road includes at least one lane associated with (e.g., identified based on) at least one lane marking.

Vehicle-to-Infrastructure (V2I) device 110 (sometimes referred to as a Vehicle-to-Infrastructure or Vehicle-to-Everything (V2X) device) includes at least one device configured to be in communication with vehicles 102 and/or V2I infrastructure system 118. In some embodiments, V2I device 110 is configured to be in communication with vehicles 102, remote AV system 114, fleet management system 116, and/or V2I system 118 via network 112. In some embodiments, V2I device 110 includes a radio frequency identification (RFID) device, signage, cameras (e.g., two-dimensional (2D) and/or three-dimensional (3D) cameras), lane markers, streetlights, parking meters, etc. In some embodiments, V2I device 110 is configured to communicate directly with vehicles 102. Additionally, or alternatively, in some embodiments V2I device 110 is configured to communicate with vehicles 102, remote AV system 114, and/or fleet management system 116 via V2I system 118. In some embodiments, V2I device 110 is configured to communicate with V2I system 118 via network 112.

Network 112 includes one or more wired and/or wireless networks. In an example, network 112 includes a cellular network (e.g., a long term evolution (LTE) network, a third generation (3G) network, a fourth generation (4G) network, a fifth generation (5G) network, a code division multiple access (CDMA) network, etc.), a public land mobile network (PLMN), a local area network (LAN), a wide area network (WAN), a metropolitan area network (MAN), a telephone network (e.g., the public switched telephone network (PSTN), a private network, an ad hoc network, an intranet, the Internet, a fiber optic-based network, a cloud computing network, etc., a combination of some or all of these networks, and/or the like.

Remote AV system 114 includes at least one device configured to be in communication with vehicles 102, V2I device 110, network 112, fleet management system 116, and/or V2I system 118 via network 112. In an example, remote AV system 114 includes a server, a group of servers, and/or other like devices. In some embodiments, remote AV system 114 is co-located with the fleet management system 116. In some embodiments, remote AV system 114 is involved in the installation of some or all of the components of a vehicle, including an autonomous system, an autonomous vehicle compute, software implemented by an autonomous vehicle compute, and/or the like. In some embodiments, remote AV system 114 maintains (e.g., updates and/or replaces) such components and/or software during the lifetime of the vehicle.

Fleet management system 116 includes at least one device configured to be in communication with vehicles 102, V2I device 110, remote AV system 114, and/or V2I infrastructure system 118. In an example, fleet management system 116 includes a server, a group of servers, and/or other like devices. In some embodiments, fleet management system 116 is associated with a ridesharing company (e.g., an organization that controls operation of multiple vehicles (e.g., vehicles that include autonomous systems and/or vehicles that do not include autonomous systems) and/or the like).

In some embodiments, V2I system 118 includes at least one device configured to be in communication with vehicles 102, V2I device 110, remote AV system 114, and/or fleet management system 116 via network 112. In some examples, V2I system 118 is configured to be in communication with V2I device 110 via a connection different from network 112. In some embodiments, V2I system 118 includes a server, a group of servers, and/or other like devices. In some embodiments, V2I system 118 is associated with a municipality or a private institution (e.g., a private institution that maintains V2I device 110 and/or the like).

The number and arrangement of elements illustrated in FIG. 1 are provided as an example. There can be additional elements, fewer elements, different elements, and/or differently arranged elements, than those illustrated in FIG. 1. Additionally, or alternatively, at least one element of environment 100 can perform one or more functions described as being performed by at least one different element of FIG. 1. Additionally, or alternatively, at least one set of elements of environment 100 can perform one or more functions described as being performed by at least one different set of elements of environment 100.

Referring now to FIG. 2, vehicle 200 (which may be the same as, or similar to vehicles 102 of FIG. 1) includes or is associated with autonomous system 202, powertrain control system 204, steering control system 206, and brake system 208. In some embodiments, vehicle 200 is the same as or similar to vehicle 102 (see FIG. 1). In some embodiments, autonomous system 202 is configured to confer vehicle 200 autonomous driving capability (e.g., implement at least one driving automation or maneuver-based function, feature, device, and/or the like that enable vehicle 200 to be partially or fully operated without human intervention including, without limitation, fully autonomous vehicles (e.g., vehicles that forego reliance on human intervention such as Level 5 ADS-operated vehicles), highly autonomous vehicles (e.g., vehicles that forego reliance on human intervention in certain situations such as Level 4 ADS-operated vehicles), conditional autonomous vehicles (e.g., vehicles that forego reliance on human intervention in limited situations such as Level 3 ADS-operated vehicles) and/or the like. In one embodiment, autonomous system 202 includes operational or tactical functionality required to operate vehicle 200 in on-road traffic and perform part or all of Dynamic Driving Task (DDT) on a sustained basis. In another embodiment, autonomous system 202 includes an Advanced Driver Assistance System (ADAS) that includes driver support features. Autonomous system 202 supports various levels of driving automation, ranging from no driving automation (e.g., Level 0) to full driving automation (e.g., Level 5). For a detailed description of fully autonomous vehicles and highly autonomous vehicles, reference may be made to SAE International's standard J3016: Taxonomy and Definitions for Terms Related to On-Road Motor Vehicle Automated Driving Systems, which is incorporated by reference in its entirety. In some embodiments, vehicle 200 is associated with an autonomous fleet manager and/or a ridesharing company.

Autonomous system 202 includes a sensor suite that includes one or more devices such as cameras 202a, LiDAR sensors 202b, radar sensors 202c, and microphones 202d. In some embodiments, autonomous system 202 can include more or fewer devices and/or different devices (e.g., ultrasonic sensors, inertial sensors, GPS receivers (discussed below), odometry sensors that generate data associated with an indication of a distance that vehicle 200 has traveled, and/or the like). In some embodiments, autonomous system 202 uses the one or more devices included in autonomous system 202 to generate data associated with environment 100, described herein. The data generated by the one or more devices of autonomous system 202 can be used by one or more systems described herein to observe the environment (e.g., environment 100) in which vehicle 200 is located. In some embodiments, autonomous system 202 includes communication device 202e, autonomous vehicle compute 202f, drive-by-wire (DBW) system 202h, and safety controller 202g.

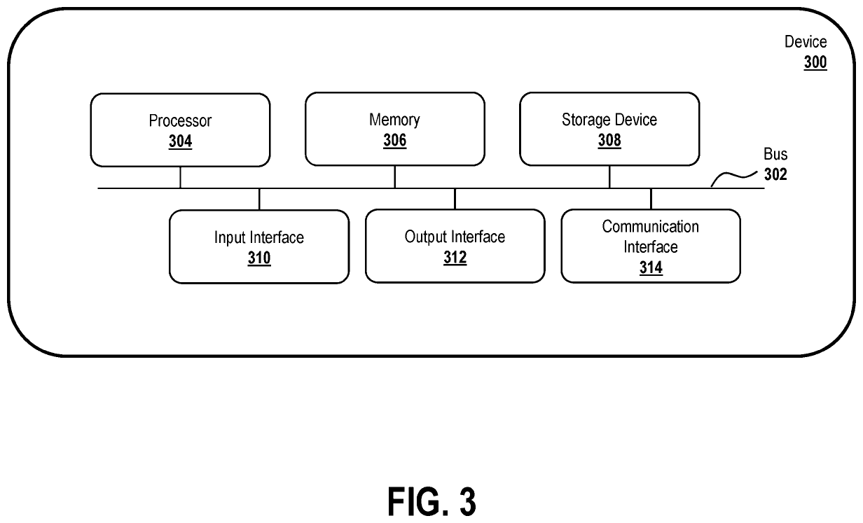

Cameras 202a include at least one device configured to be in communication with communication device 202e, autonomous vehicle compute 202f, and/or safety controller 202g via a bus (e.g., a bus that is the same as or similar to bus 302 of FIG. 3). Cameras 202a include at least one camera (e.g., a digital camera using a light sensor such as a Charge-Coupled Device (CCD), a thermal camera, an infrared (IR) camera, an event camera, and/or the like) to capture images including physical objects (e.g., cars, buses, curbs, people, and/or the like). In some embodiments, camera 202a generates camera data as output. In some examples, camera 202a generates camera data that includes image data associated with an image. In this example, the image data may specify at least one parameter (e.g., image characteristics such as exposure, brightness, etc., an image timestamp, and/or the like) corresponding to the image. In such an example, the image may be in a format (e.g., RAW, JPEG, PNG, and/or the like). In some embodiments, camera 202a includes a plurality of independent cameras configured on (e.g., positioned on) a vehicle to capture images for the purpose of stereopsis (stereo vision). In some examples, camera 202a includes a plurality of cameras that generate image data and transmit the image data to autonomous vehicle compute 202f and/or a fleet management system (e.g., a fleet management system that is the same as or similar to fleet management system 116 of FIG. 1). In such an example, autonomous vehicle compute 202f determines depth to one or more objects in a field of view of at least two cameras of the plurality of cameras based on the image data from the at least two cameras. In some embodiments, cameras 202a is configured to capture images of objects within a distance from cameras 202a (e.g., up to 100 meters, up to a kilometer, and/or the like). Accordingly, cameras 202a include features such as sensors and lenses that are optimized for perceiving objects that are at one or more distances from cameras 202a.

In an embodiment, camera 202a includes at least one camera configured to capture one or more images associated with one or more traffic lights, street signs and/or other physical objects that provide visual navigation information. In some embodiments, camera 202a generates traffic light data associated with one or more images. In some examples, camera 202a generates TLD (Traffic Light Detection) data associated with one or more images that include a format (e.g., RAW, JPEG, PNG, and/or the like). In some embodiments, camera 202a that generates TLD data differs from other systems described herein incorporating cameras in that camera 202a can include one or more cameras with a wide field of view (e.g., a wide-angle lens, a fish-eye lens, a lens having a viewing angle of approximately 120 degrees or more, and/or the like) to generate images about as many physical objects as possible.

Light Detection and Ranging (LiDAR) sensors 202b include at least one device configured to be in communication with communication device 202e, autonomous vehicle compute 202f, and/or safety controller 202g via a bus (e.g., a bus that is the same as or similar to bus 302 of FIG. 3). LiDAR sensors 202b include a system configured to transmit light from a light emitter (e.g., a laser transmitter). Light emitted by LiDAR sensors 202b include light (e.g., infrared light and/or the like) that is outside of the visible spectrum. In some embodiments, during operation, light emitted by LiDAR sensors 202b encounters a physical object (e.g., a vehicle) and is reflected back to LiDAR sensors 202b. In some embodiments, the light emitted by LiDAR sensors 202b does not penetrate the physical objects that the light encounters. LiDAR sensors 202b also include at least one light detector which detects the light that was emitted from the light emitter after the light encounters a physical object. In some embodiments, at least one data processing system associated with LiDAR sensors 202b generates an image (e.g., a point cloud, a combined point cloud, and/or the like) representing the objects included in a field of view of LiDAR sensors 202b. In some examples, the at least one data processing system associated with LiDAR sensor 202b generates an image that represents the boundaries of a physical object, the surfaces (e.g., the topology of the surfaces) of the physical object, and/or the like. In such an example, the image is used to determine the boundaries of physical objects in the field of view of LiDAR sensors 202b.

Radio Detection and Ranging (radar) sensors 202c include at least one device configured to be in communication with communication device 202e, autonomous vehicle compute 202f, and/or safety controller 202g via a bus (e.g., a bus that is the same as or similar to bus 302 of FIG. 3). Radar sensors 202c include a system configured to transmit radio waves (either pulsed or continuously). The radio waves transmitted by radar sensors 202c include radio waves that are within a predetermined spectrum. In some embodiments, during operation, radio waves transmitted by radar sensors 202c encounter a physical object and are reflected back to radar sensors 202c. In some embodiments, the radio waves transmitted by radar sensors 202c are not reflected by some objects. In some embodiments, at least one data processing system associated with radar sensors 202c generates signals representing the objects included in a field of view of radar sensors 202c. For example, the at least one data processing system associated with radar sensor 202c generates an image that represents the boundaries of a physical object, the surfaces (e.g., the topology of the surfaces) of the physical object, and/or the like. In some examples, the image is used to determine the boundaries of physical objects in the field of view of radar sensors 202c.

Microphones 202d includes at least one device configured to be in communication with communication device 202e, autonomous vehicle compute 202f, and/or safety controller 202g via a bus (e.g., a bus that is the same as or similar to bus 302 of FIG. 3). Microphones 202d include one or more microphones (e.g., array microphones, external microphones, and/or the like) that capture audio signals and generate data associated with (e.g., representing) the audio signals. In some examples, microphones 202d include transducer devices and/or like devices. In some embodiments, one or more systems described herein can receive the data generated by microphones 202d and determine a position of an object relative to vehicle 200 (e.g., a distance and/or the like) based on the audio signals associated with the data.

Communication device 202e includes at least one device configured to be in communication with cameras 202a, LiDAR sensors 202b, radar sensors 202c, microphones 202d, autonomous vehicle compute 202f, safety controller 202g, and/or DBW (Drive-By-Wire) system 202h. For example, communication device 202e may include a device that is the same as or similar to communication interface 314 of FIG. 3. In some embodiments, communication device 202e includes a vehicle-to-vehicle (V2V) communication device (e.g., a device that enables wireless communication of data between vehicles).

Autonomous vehicle compute 202f include at least one device configured to be in communication with cameras 202a, LiDAR sensors 202b, radar sensors 202c, microphones 202d, communication device 202e, safety controller 202g, and/or DBW system 202h. In some examples, autonomous vehicle compute 202f includes a device such as a client device, a mobile device (e.g., a cellular telephone, a tablet, and/or the like), a server (e.g., a computing device including one or more central processing units, graphical processing units, and/or the like), and/or the like. In some embodiments, autonomous vehicle compute 202f is the same as or similar to autonomous vehicle compute 400, described herein. Additionally, or alternatively, in some embodiments autonomous vehicle compute 202f is configured to be in communication with an autonomous vehicle system (e.g., an autonomous vehicle system that is the same as or similar to remote AV system 114 of FIG. 1), a fleet management system (e.g., a fleet management system that is the same as or similar to fleet management system 116 of FIG. 1), a V2I device (e.g., a V2I device that is the same as or similar to V2I device 110 of FIG. 1), and/or a V2I system (e.g., a V2I system that is the same as or similar to V2I system 118 of FIG. 1).

Safety controller 202g includes at least one device configured to be in communication with cameras 202a, LiDAR sensors 202b, radar sensors 202c, microphones 202d, communication device 202e, autonomous vehicle computer 202f, and/or DBW system 202h. In some examples, safety controller 202g includes one or more controllers (electrical controllers, electromechanical controllers, and/or the like) that are configured to generate and/or transmit control signals to operate one or more devices of vehicle 200 (e.g., powertrain control system 204, steering control system 206, brake system 208, and/or the like). In some embodiments, safety controller 202g is configured to generate control signals that take precedence over (e.g., overrides) control signals generated and/or transmitted by autonomous vehicle compute 202f.

DBW system 202h includes at least one device configured to be in communication with communication device 202e and/or autonomous vehicle compute 202f. In some examples, DBW system 202h includes one or more controllers (e.g., electrical controllers, electromechanical controllers, and/or the like) that are configured to generate and/or transmit control signals to operate one or more devices of vehicle 200 (e.g., powertrain control system 204, steering control system 206, brake system 208, and/or the like). Additionally, or alternatively, the one or more controllers of DBW system 202h are configured to generate and/or transmit control signals to operate at least one different device (e.g., a turn signal, headlights, door locks, windshield wipers, and/or the like) of vehicle 200.

Powertrain control system 204 includes at least one device configured to be in communication with DBW system 202h. In some examples, powertrain control system 204 includes at least one controller, actuator, and/or the like. In some embodiments, powertrain control system 204 receives control signals from DBW system 202h and powertrain control system 204 causes vehicle 200 to make longitudinal vehicle motion, such as start moving forward, stop moving forward, start moving backward, stop moving backward, accelerate in a direction, decelerate in a direction or to make lateral vehicle motion such as performing a left turn, performing a right turn, and/or the like. In an example, powertrain control system 204 causes the energy (e.g., fuel, electricity, and/or the like) provided to a motor of the vehicle to increase, remain the same, or decrease, thereby causing at least one wheel of vehicle 200 to rotate or not rotate.

Steering control system 206 includes at least one device configured to rotate one or more wheels of vehicle 200. In some examples, steering control system 206 includes at least one controller, actuator, and/or the like. In some embodiments, steering control system 206 causes the front two wheels and/or the rear two wheels of vehicle 200 to rotate to the left or right to cause vehicle 200 to turn to the left or right. In other words, steering control system 206 causes activities necessary for the regulation of the y-axis component of vehicle motion.

Brake system 208 includes at least one device configured to actuate one or more brakes to cause vehicle 200 to reduce speed and/or remain stationary. In some examples, brake system 208 includes at least one controller and/or actuator that is configured to cause one or more calipers associated with one or more wheels of vehicle 200 to close on a corresponding rotor of vehicle 200. Additionally, or alternatively, in some examples brake system 208 includes an automatic emergency braking (AEB) system, a regenerative braking system, and/or the like.

In some embodiments, vehicle 200 includes at least one platform sensor (not explicitly illustrated) that measures or infers properties of a state or a condition of vehicle 200. In some examples, vehicle 200 includes platform sensors such as a global positioning system (GPS) receiver, an inertial measurement unit (IMU), a wheel speed sensor, a wheel brake pressure sensor, a wheel torque sensor, an engine torque sensor, a steering angle sensor, and/or the like. Although brake system 208 is illustrated to be located in the near side of vehicle 200 in FIG. 2, brake system 208 may be located anywhere in vehicle 200.

Referring now to FIG. 3, illustrated is a schematic diagram of a device 300. As illustrated, device 300 includes processor 304, memory 306, storage component 308, input interface 310, output interface 312, communication interface 314, and bus 302. In some embodiments, device 300 corresponds to at least one device of vehicles 102 (e.g., at least one device of a system of vehicles 102) and/or one or more devices of network 112 (e.g., one or more devices of a system of network 112). In some embodiments, one or more devices of vehicles 102 (e.g., one or more devices of a system of vehicles 102) and/or one or more devices of network 112 (e.g., one or more devices of a system of network 112) include at least one device 300 and/or at least one component of device 300. As shown in FIG. 3, device 300 includes bus 302, processor 304, memory 306, storage component 308, input interface 310, output interface 312, and communication interface 314.

Bus 302 includes a component that permits communication among the components of device 300. In some cases, processor 304 includes a processor (e.g., a central processing unit (CPU), a graphics processing unit (GPU), an accelerated processing unit (APU), and/or the like), a microphone, a digital signal processor (DSP), and/or any processing component (e.g., a field-programmable gate array (FPGA), an application specific integrated circuit (ASIC), and/or the like) that can be programmed to perform at least one function. Memory 306 includes random access memory (RAM), read-only memory (ROM), and/or another type of dynamic and/or static storage device (e.g., flash memory, magnetic memory, optical memory, and/or the like) that stores data and/or instructions for use by processor 304.

Storage component 308 stores data and/or software related to the operation and use of device 300. In some examples, storage component 308 includes a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive.

Input interface 310 includes a component that permits device 300 to receive information, such as via user input (e.g., a touchscreen display, a keyboard, a keypad, a mouse, a button, a switch, a microphone, a camera, and/or the like). Additionally or alternatively, in some embodiments input interface 310 includes a sensor that senses information (e.g., a global positioning system (GPS) receiver, an accelerometer, a gyroscope, an actuator, and/or the like). Output interface 312 includes a component that provides output information from device 300 (e.g., a display, a speaker, one or more light-emitting diodes (LEDs), and/or the like).

In some embodiments, communication interface 314 includes a transceiver-like component (e.g., a transceiver, a separate receiver and transmitter, and/or the like) that permits device 300 to communicate with other devices via a wired connection, a wireless connection, or a combination of wired and wireless connections. In some examples, communication interface 314 permits device 300 to receive information from another device and/or provide information to another device. In some examples, communication interface 314 includes an Ethernet interface, an optical interface, a coaxial interface, an infrared interface, a radio frequency (RF) interface, a universal serial bus (USB) interface, a Wi-Fi® interface, a cellular network interface, and/or the like.

In some embodiments, device 300 performs one or more processes described herein. Device 300 performs these processes based on processor 304 executing software instructions stored by a computer-readable medium, such as memory 305 and/or storage component 308. A computer-readable medium (e.g., a non-transitory computer readable medium) is defined herein as a non-transitory memory device. A non-transitory memory device includes memory space located inside a single physical storage device or memory space spread across multiple physical storage devices.

In some embodiments, software instructions are read into memory 306 and/or storage component 308 from another computer-readable medium or from another device via communication interface 314. When executed, software instructions stored in memory 306 and/or storage component 308 cause processor 304 to perform one or more processes described herein. Additionally or alternatively, hardwired circuitry is used in place of or in combination with software instructions to perform one or more processes described herein. Thus, embodiments described herein are not limited to any specific combination of hardware circuitry and software unless explicitly stated otherwise.

Memory 306 and/or storage component 308 includes data storage or at least one data structure (e.g., a database and/or the like). Device 300 is capable of receiving information from, storing information in, communicating information to, or searching information stored in the data storage or the at least one data structure in memory 306 or storage component 308. In some examples, the information includes network data, input data, output data, or any combination thereof.

In some embodiments, device 300 is configured to execute software instructions that are either stored in memory 306 and/or in the memory of another device (e.g., another device that is the same as or similar to device 300). As used herein, the term “module” refers to at least one instruction stored in memory 306 and/or in the memory of another device that, when executed by processor 304 and/or by a processor of another device (e.g., another device that is the same as or similar to device 300) cause device 300 (e.g., at least one component of device 300) to perform one or more processes described herein. In some embodiments, a module is implemented in software, firmware, hardware, and/or the like.

The number and arrangement of components illustrated in FIG. 3 are provided as an example. In some embodiments, device 300 can include additional components, fewer components, different components, or differently arranged components than those illustrated in FIG. 3. Additionally or alternatively, a set of components (e.g., one or more components) of device 300 can perform one or more functions described as being performed by another component or another set of components of device 300.

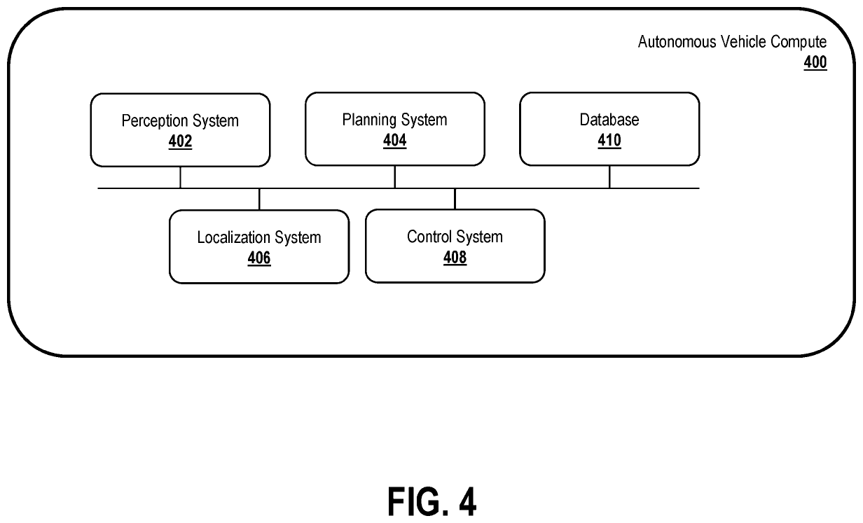

Referring now to FIG. 4, illustrated is an example block diagram of an autonomous vehicle compute 400 (sometimes referred to as an “AV stack”). As illustrated, autonomous vehicle compute 400 includes perception system 402 (sometimes referred to as a perception module), planning system 404 (sometimes referred to as a planning module), localization system 406 (sometimes referred to as a localization module), control system 408 (sometimes referred to as a control module), and database 410. In some embodiments, perception system 402, planning system 404, localization system 406, control system 408, and database 410 are included and/or implemented in an autonomous navigation system of a vehicle (e.g., autonomous vehicle compute 202f of vehicle 200). Additionally, or alternatively, in some embodiments perception system 402, planning system 404, localization system 406, control system 408, and database 410 are included in one or more standalone systems (e.g., one or more systems that are the same as or similar to autonomous vehicle compute 400 and/or the like). In some examples, perception system 402, planning system 404, localization system 406, control system 408, and database 410 are included in one or more standalone systems that are located in a vehicle and/or at least one remote system as described herein. In some embodiments, any and/or all of the systems included in autonomous vehicle compute 400 are implemented in software (e.g., in software instructions stored in memory), computer hardware (e.g., by microprocessors, microcontrollers, application-specific integrated circuits (ASICs), Field Programmable Gate Arrays (FPGAs), and/or the like), or combinations of computer software and computer hardware. It will also be understood that, in some embodiments, autonomous vehicle compute 400 is configured to be in communication with a remote system (e.g., an autonomous vehicle system that is the same as or similar to remote AV system 114, a fleet management system 116 that is the same as or similar to fleet management system 116, a V2I system that is the same as or similar to V2I system 118, and/or the like).

In some embodiments, perception system 402 receives data associated with at least one physical object (e.g., data that is used by perception system 402 to detect the at least one physical object) in an environment and classifies the at least one physical object. In some examples, perception system 402 receives image data captured by at least one camera (e.g., cameras 202a), the image associated with (e.g., representing) one or more physical objects within a field of view of the at least one camera. In such an example, perception system 402 classifies at least one physical object based on one or more groupings of physical objects (e.g., bicycles, vehicles, traffic signs, pedestrians, and/or the like). In some embodiments, perception system 402 transmits data associated with the classification of the physical objects to planning system 404 based on perception system 402 classifying the physical objects.

In some embodiments, planning system 404 receives data associated with a destination and generates data associated with at least one route (e.g., routes 106) along which a vehicle (e.g., vehicles 102) can travel along toward a destination. In some embodiments, planning system 404 periodically or continuously receives data from perception system 402 (e.g., data associated with the classification of physical objects, described above) and planning system 404 updates the at least one trajectory or generates at least one different trajectory based on the data generated by perception system 402. In other words, planning system 404 may perform tactical function-related tasks that are required to operate vehicle 102 in on-road traffic. Tactical efforts involve maneuvering the vehicle in traffic during a trip, including but not limited to deciding whether and when to overtake another vehicle, change lanes, or selecting an appropriate speed, acceleration, deacceleration, etc. In some embodiments, planning system 404 receives data associated with an updated position of a vehicle (e.g., vehicles 102) from localization system 406 and planning system 404 updates the at least one trajectory or generates at least one different trajectory based on the data generated by localization system 406.

In some embodiments, localization system 406 receives data associated with (e.g., representing) a location of a vehicle (e.g., vehicles 102) in an area. In some examples, localization system 406 receives LiDAR data associated with at least one point cloud generated by at least one LiDAR sensor (e.g., LiDAR sensors 202b). In certain examples, localization system 406 receives data associated with at least one point cloud from multiple LiDAR sensors and localization system 406 generates a combined point cloud based on each of the point clouds. In these examples, localization system 406 compares the at least one point cloud or the combined point cloud to two-dimensional (2D) and/or a three-dimensional (3D) map of the area stored in database 410. Localization system 406 then determines the position of the vehicle in the area based on localization system 406 comparing the at least one point cloud or the combined point cloud to the map. In some embodiments, the map includes a combined point cloud of the area generated prior to navigation of the vehicle. In some embodiments, maps include, without limitation, high-precision maps of the roadway geometric properties, maps describing road network connectivity properties, maps describing roadway physical properties (such as traffic speed, traffic volume, the number of vehicular and cyclist traffic lanes, lane width, lane traffic directions, or lane marker types and locations, or combinations thereof), and maps describing the spatial locations of road features such as crosswalks, traffic signs or other travel signals of various types. In some embodiments, the map is generated in real-time based on the data received by the perception system.

In another example, localization system 406 receives Global Navigation Satellite System (GNSS) data generated by a global positioning system (GPS) receiver. In some examples, localization system 406 receives GNSS data associated with the location of the vehicle in the area and localization system 406 determines a latitude and longitude of the vehicle in the area. In such an example, localization system 406 determines the position of the vehicle in the area based on the latitude and longitude of the vehicle. In some embodiments, localization system 406 generates data associated with the position of the vehicle. In some examples, localization system 406 generates data associated with the position of the vehicle based on localization system 406 determining the position of the vehicle. In such an example, the data associated with the position of the vehicle includes data associated with one or more semantic properties corresponding to the position of the vehicle.

In some embodiments, control system 408 receives data associated with at least one trajectory from planning system 404 and control system 408 controls operation of the vehicle. In some examples, control system 408 receives data associated with at least one trajectory from planning system 404 and control system 408 controls operation of the vehicle by generating and transmitting control signals to cause a powertrain control system (e.g., DBW system 202h, powertrain control system 204, and/or the like), a steering control system (e.g., steering control system 206), and/or a brake system (e.g., brake system 208) to operate. For example, control system 408 is configured to perform operational functions such as a lateral vehicle motion control or a longitudinal vehicle motion control. The lateral vehicle motion control causes activities necessary for the regulation of the y-axis component of vehicle motion. The longitudinal vehicle motion control causes activities necessary for the regulation of the x-axis component of vehicle motion. In an example, where a trajectory includes a left turn, control system 408 transmits a control signal to cause steering control system 206 to adjust a steering angle of vehicle 200, thereby causing vehicle 200 to turn left. Additionally, or alternatively, control system 408 generates and transmits control signals to cause other devices (e.g., headlights, turn signal, door locks, windshield wipers, and/or the like) of vehicle 200 to change states.

In some embodiments, perception system 402, planning system 404, localization system 406, and/or control system 408 implement at least one machine learning model (e.g., at least one multilayer perceptron (MLP), at least one convolutional neural network (CNN), at least one recurrent neural network (RNN), at least one autoencoder, at least one transformer, and/or the like). In some examples, perception system 402, planning system 404, localization system 406, and/or control system 408 implement at least one machine learning model alone or in combination with one or more of the above-noted systems. In some examples, perception system 402, planning system 404, localization system 406, and/or control system 408 implement at least one machine learning model as part of a pipeline (e.g., a pipeline for identifying one or more objects located in an environment and/or the like).

Database 410 stores data that is transmitted to, received from, and/or updated by perception system 402, planning system 404, localization system 406 and/or control system 408. In some examples, database 410 includes a storage component (e.g., a storage component that is the same as or similar to storage component 308 of FIG. 3) that stores data and/or software related to the operation and uses at least one system of autonomous vehicle compute 400. In some embodiments, database 410 stores data associated with 2D and/or 3D maps of at least one area. In some examples, database 410 stores data associated with 2D and/or 3D maps of a portion of a city, multiple portions of multiple cities, multiple cities, a county, a state, a State (e.g., a country), and/or the like). In such an example, a vehicle (e.g., a vehicle that is the same as or similar to vehicles 102 and/or vehicle 200) can drive along one or more drivable regions (e.g., single-lane roads, multi-lane roads, highways, back roads, off road trails, and/or the like) and cause at least one LiDAR sensor (e.g., a LiDAR sensor that is the same as or similar to LiDAR sensors 202b) to generate data associated with an image representing the objects included in a field of view of the at least one LiDAR sensor.

In some embodiments, database 410 can be implemented across a plurality of devices. In some examples, database 410 is included in a vehicle (e.g., a vehicle that is the same as or similar to vehicles 102 and/or vehicle 200), an autonomous vehicle system (e.g., an autonomous vehicle system that is the same as or similar to remote AV system 114, a fleet management system (e.g., a fleet management system that is the same as or similar to fleet management system 116 of FIG. 1, a V2I system (e.g., a V2I system that is the same as or similar to V2I system 118 of FIG. 1) and/or the like.

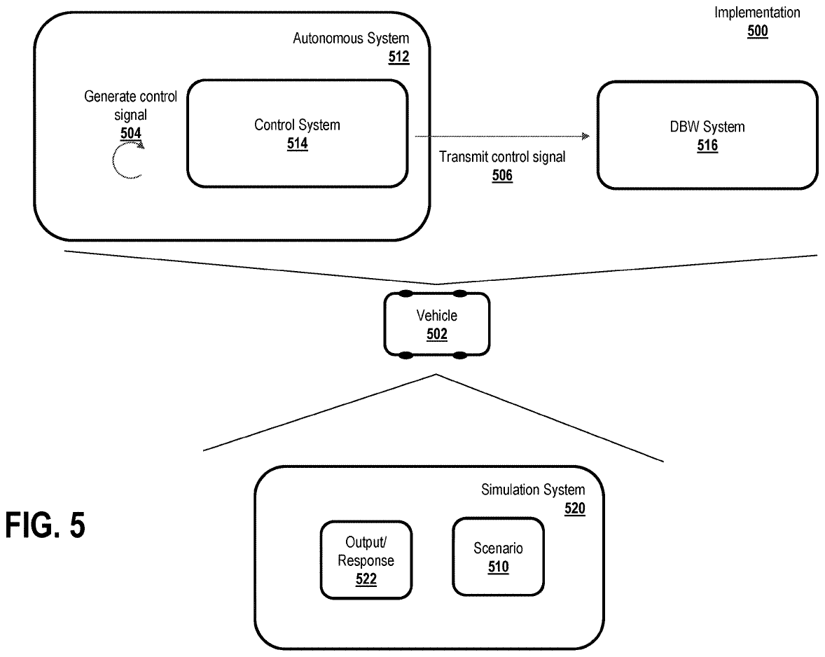

Referring now to FIG. 5, illustrated are diagrams of an implementation 500 of a process for simulated smart pedestrians. In some embodiments, implementation 500 includes a vehicle 502 that operates according to outputs generated by autonomous system 512 and DBW system 516. In some embodiments, Autonomous system 512 is the same as or similar to autonomous system 202 of FIG. 2, the control system 514 is the same as or similar to the control system 408 of FIG. 4, and DBW system 516 is the same as or similar to DBW system 202h of FIG. 2. In examples, a control system 514 generates control signals (504). The autonomous system 512 controls operation of the vehicle 502 by generating and transmitting control signals (506) to cause a DBW system 516 to operate.

In some embodiments, inputs to the vehicle 502 are simulated by at least one scenario(s) 510. Scenarios 510 include inputs to the vehicle 502 that are obtained by one or more devices, subsystems, or systems of the autonomous system 512 during a simulation. In examples, the scenarios 510 include data associated with an environment, such as the environment 100 of FIG. 1. In examples, a simulation refers to the inputting of time series data representing a scenario to an autonomous system 512. The time series data is, for example, sensor data, data associated with vehicle dynamics, data associated with pedestrian dynamics, and the like. In examples, the time series data includes perception data, sensor data, vehicle dynamics, environmental data, and the like. In examples, the scenario includes frames of data, where a frame is a set of time series data at a specified point in time. In some embodiments, frames of data included in a scenario are input to an autonomous system (e.g., during a simulation), and the output or response of the autonomous system to the frames of data is obtained to inform subsequent frames of data in the scenario. The subsequent frames of data are executed during the same simulation.

In the real world, features of the environment, such as objects (e.g., objects 104a-104n of FIG. 1) and other physical attributes or occurrences, are represented in data captured by one or more devices of an autonomous system. Output data generated by the one or more devices or systems of an autonomous system is used to observe and move through the environment. Devices or systems include, for example, a communication device, autonomous vehicle compute, drive-by-wire (DBW) system, or safety controller.

In a simulation, one or more scenarios 510 (including data associated with an environment) are provided to an autonomous system 512 in a controlled environment. The configuration and format of the data included in the scenarios is based on, at least in part, the one or more devices or systems of the autonomous system under test during the simulation. In examples, during a simulation data is input to one or more of the communication device, autonomous vehicle compute, drive-by-wire (DBW) system, or safety controller. The communication device, autonomous vehicle compute, drive-by-wire (DBW) system, and safety controller used during a simulation are the same as or similar to the communication device 202e, autonomous vehicle compute 202f, drive-by-wire (DBW) system 202h, and safety controller 202g of FIG. 2, respectively. A simulation system 520 obtains output 522 from the autonomous system 512 in response to the scenarios 510. In some embodiments, the simulation system 520 dynamically and iteratively updates the scenario input to the autonomous system 512 according to the output or response 522 of the autonomous system 512. The response of the one or more devices to the scenario is observed, and the one or more devices are iteratively improved or developed based on an evaluation of the response, the scenario, or any combinations thereof.

For ease of explanation, particular devices, systems, and subsystems are described as obtaining data in at least one scenario during a simulation, however any devices, systems, or subsystems can be used according to the present techniques. In examples, the controlled environment associated with simulation refers to a computing test environment on a server or at a cloud location where software associated with the devices, systems, subsystems execute in response to the scenario. Autonomous systems that execute in a computing test environment may be “offline” systems. In examples, the controlled environment associated with simulation refers to a physical test environment where software associated with the devices, systems, and subsystems execute on a vehicle in response to the scenario. Autonomous systems that execute in on a vehicle may be “online” systems.

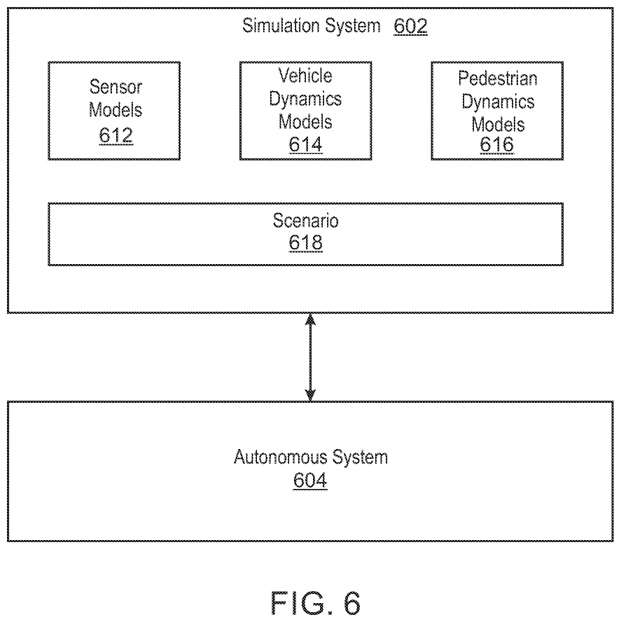

FIG. 6 shows a simulation infrastructure 600. The simulation infrastructure 600 enables simulated smart pedestrians. For ease of description, the present techniques are described using an autonomous vehicle as an autonomous system 604. However, data associated with an environment is generated and iteratively input to any autonomous system according to the present techniques. In examples, simulations enable testing of autonomous vehicles to ensure the autonomous vehicles operate in a safe and error-free manner. The simulation infrastructure 600 includes a simulation system 602 and the autonomous system 604. The simulation system 602 is the same as or similar to simulation system 520 of FIG. 5. The autonomous system 604 is the same as or similar to the autonomous system 512 of FIG. 5. As shown in FIG. 6, the autonomous system 604 is communicatively coupled with the simulation system 602. In examples, the autonomous system 606 is offline (e.g., does not execute on a deployed vehicle).

The simulation system 602 includes at least one sensor model 612, at least one vehicle dynamics model 614, and at least one pedestrian dynamics model 616. The outputs of the sensor models 612, the vehicle dynamics models 614, and the pedestrian dynamics models 616 are used to update or create at least one scenario 618 (e.g., scenarios 510 of FIG. 5). In some embodiments a scenario is time series data output by sensor models 612, vehicle dynamics models 614, pedestrian dynamics models 616, or any combinations thereof. In examples, the simulation system aggregates the outputs of the sensor models 612, the vehicle dynamics models 614, and the pedestrian dynamics models 616 at a series of timestamps. For example, the vehicle dynamics data and pedestrian dynamics data are used to constrain the sensor data associated with the environment. In an example, the sensor models generate sensor data of an environment based on vehicle dynamics that occur responsive to features of the environment. Particular sensor data, such as data from a wheel speed sensor, is simulated according to a vehicle dynamics model or vehicle dynamics data. In an example, the sensor models generate sensor data of an environment based on pedestrian dynamics that occur responsive to features the environment. Particular sensor data, such as data from a camera, is simulated according to a pedestrian dynamics model or pedestrian dynamics data. In this example, the camera data includes motion of the pedestrian across frames of a scenario. In another example, particular sensor data, such as data from a LiDAR, is simulated according to a pedestrian dynamics model or pedestrian dynamics data. In this example, the LiDAR data includes point cloud data corresponding to a respective pedestrian across frames of a scenario. Aggregated data at each respective timestamp forms frames of a scenario.

The sensor models 612 generate simulated sensor data that is input to the autonomous system 604 during a simulation. For example, the sensor models 612 generate data associated with one or more sensor or devices such as cameras 202a, LiDAR sensors 202b, radar sensors 202c, microphones 202d, and communication device 202e as described with respect to FIG. 2. The sensor models 612 generate sensor data that is associated with at least one simulated object in a controlled environment. In examples, the sensor models 612 generate sensor data as captured by devices such as cameras, LiDAR sensors, radar sensors, microphones, communication devices, or any combinations thereof. In examples, the sensor models 612 generate data as input to systems including the perception system 402, planning system 404, localization system 406, control system 408, or database 410 as described with respect to FIG. 4. In some examples, the sensor models 612 generate data as output by systems including the perception system 402, planning system 404, localization system 406, control system 408, or database 410 as described with respect to FIG. 4. In examples, the particular type of data generated by the sensor models 612 is based on, at least in part, a configuration of the autonomous system where the data generated by the sensor models corresponds to the devices, subsystems, and systems available for simulation.

Vehicle dynamics models 614 generate data representative of vehicle motion. In examples, vehicle dynamics include data associated with the motion of the autonomous system. The vehicle dynamics models 614 characterize how the autonomous system behaves in motion. For example, the vehicle dynamics models 614 generates data output by one or more devices such as drive-by-wire (DBW) system 202h, safety controller 202g, powertrain control system 204, steering control system 206, and brake system 208. In examples, output of the autonomous system 604 is obtained and input to the vehicle dynamics models 614 during a simulation. The simulation infrastructure 600 enables the simulation of vehicle behaviors such as varying steering profiles, acceleration profiles, tire parameters, and the like responsive to output of the autonomous system 604. Accordingly, the vehicle dynamics models 614 include models that generate outputs to a drive-by-wire (DBW) system, safety controller, powertrain control system, steering control system, brake system, or any combinations thereof in view of vehicle behaviors (e.g., varying steering profiles, acceleration profiles, tire parameters, and the like) associated with the autonomous system. In examples, the vehicle dynamics models 614 mimic the vehicle dynamics associated with a real world vehicle, and iteratively updates the scenario during a simulation in accordance with the vehicle behaviors.

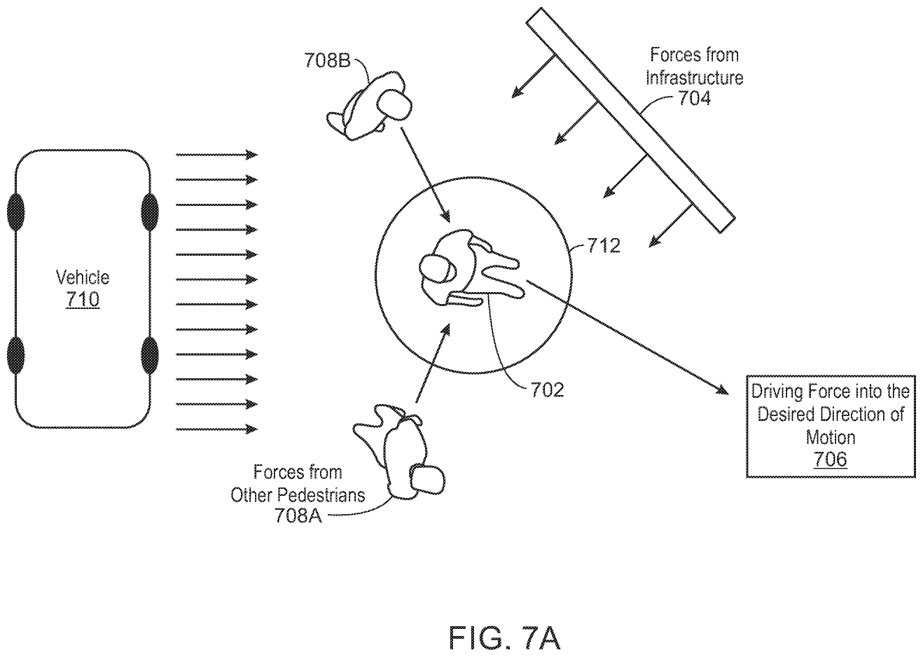

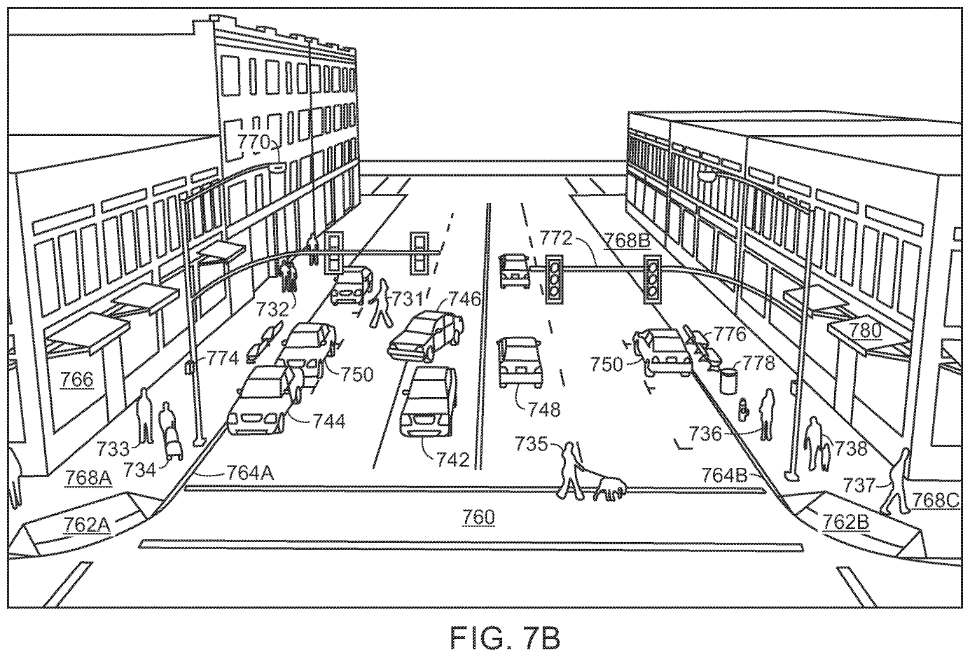

Pedestrian dynamics models 616 output data representative of pedestrian motion. In examples, the pedestrian dynamics models 616 generates data associated with smart pedestrians. The smart pedestrians are iteratively spawned at timestamps of the scenarios 618. In examples, the smart pedestrians behave (e.g., exhibit observable behaviors) in a scenario according to at least one behavior model, such as a social force model described with respect to FIG. 7A. Input to the pedestrian dynamics models 616 includes, for example, data associated with an environment including physical objects (cars, buses, curbs, cyclists, people, and/or the like), traffic infrastructure, signals, and signs (e.g., roadways, sidewalks, traffic control lights, traffic control signs), structures (e.g., a building, a sign, a fire hydrant, etc.), weather conditions (e.g., temperature, rain, sleet, snow, wind), time of day, terrain or landscape information, or any combination thereof. The pedestrian dynamics models 616 enable the creation of scenarios 618 with pedestrians that interact with features of the simulated environment. In examples, smart pedestrians are pedestrians that are aware of the features of the simulated environment and exhibit behaviors based on the impact of the features on a respective pedestrian. The pedestrian awareness and behaviors vary in response to the features within the simulated environment. The features of the simulated environment are, for example, other objects (e.g., cars, buses, curbs, people, and/or the like), traffic infrastructure, signals, and signs (e.g., roadways, sidewalks, traffic control lights, traffic control signs), structures (e.g., a building, a sign, a fire hydrant, etc.), weather conditions (e.g., temperature, rain, sleet, snow, wind), time of day, terrain or landscape information, and the like. During a simulation, the data associated with a smart pedestrian varies in response to features of the simulated environment by a velocity, acceleration, heading, or other behavior output by the pedestrian dynamics model changing to reflect a reaction (e.g., change in velocity, acceleration, heading, or behavior) of the pedestrian to the feature.

In examples, the simulation system aggregates the outputs of the sensor models 612, the vehicle dynamics models 614, and the pedestrian dynamics models 616 at a series of timestamps to form scenarios 618. For example, the sensor models generate sensor data in accordance with the outputs of the vehicle dynamics models 614, pedestrian dynamics models 616, or any combinations thereof. In examples, the sensor models 612, the vehicle dynamics models 614, and the pedestrian dynamics models 616 update their respective output responsive to the output of the autonomous system 604 during a simulation. The insertion of smart pedestrians in the scenarios during simulation enables development of autonomous system solutions in view of realistic pedestrian behavior without endangering humans and without real world pedestrian-vehicle conflicts. Scenarios that include contact and close contact between vehicles and pedestrians (not possible in the real-world due to the danger to human life resulting in such contacts) are implemented in scenarios according to the present techniques. The present techniques improve simulation technology by modeling vehicle-pedestrian interactions as described herein.

FIG. 7A is an illustration of a social force model 700. The social force model 700 responds to forces acting on a smart pedestrian 702, and includes other parameters that govern pedestrian movement, including the path traversed by the pedestrian, the velocity of the pedestrian, and the like. In examples, the social force model 700 describes and models pedestrian behavior as if a pedestrian moves through an environment subject to external forces. The modeled pedestrian behavior is based on an optimal direction of movement of the smart pedestrian from a current location to a goal location in view of the smart pedestrian's capabilities while maintaining level of safety and/or comfort when navigating the environment. In examples, a pedestrian dynamics model (e.g., pedestrian dynamics model 614 of FIG. 6) is the same as, or similar to, a social force model 700 of FIG. 7. A pedestrian dynamics model is associated with a respective pedestrian. In examples, a pedestrian dynamics model outputs a heading and velocity associated with a respective pedestrian at each timestamp of a scenario according to the attributes implemented by the pedestrian dynamics model.

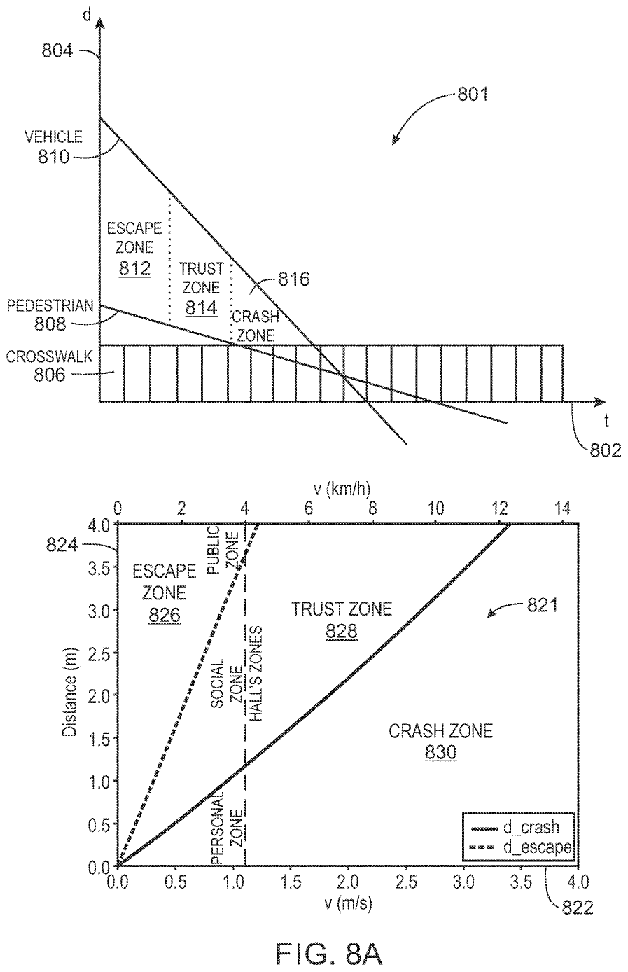

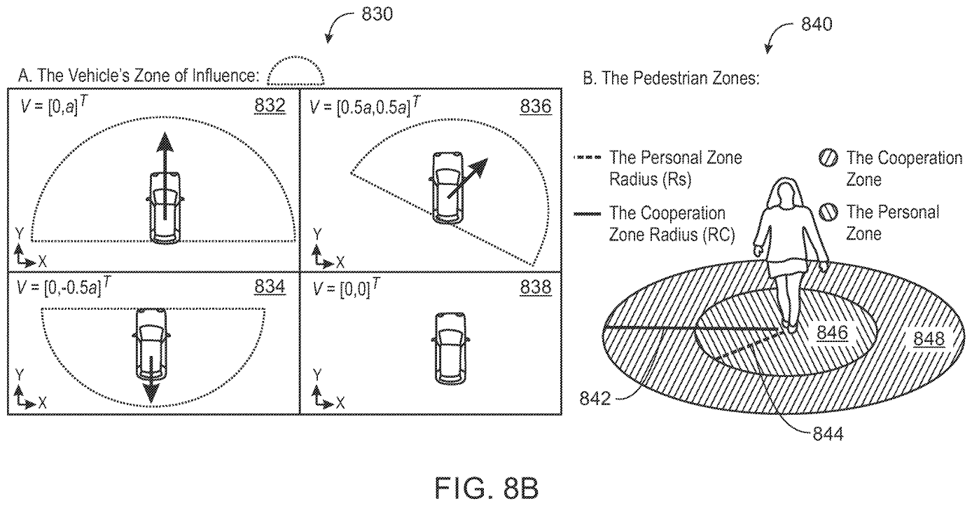

In the example of FIG. 7A, the forces include structural forces 704 from structures in the environment, a driving force 706 into the desired direction of motion of the pedestrian, forces from other pedestrians 708A and 708B, and forces from vehicles 710. Additional forces are described with respect to FIG. 7B. The magnitude of forces associated with a pedestrian are based on the respective pedestrian model that determines the pedestrian's reaction to a force. In examples, the reaction or behavior of a smart pedestrian is determined according to one or more attributes of the respective pedestrian dynamics model. Various attributes are used to describe the behavior of a smart pedestrian. For example, a comfortability attribute defines how a pedestrian behaves in view of route difficulty and length. Pedestrians seek comfortable routes, and will move along routes that provide physical ease to reach respective destinations as comfortably as possible. However, pedestrians balance physical ease with the length of a route. In examples, pedestrians take the shortest possible path to reach respective destinations. A physical trust attribute defines the comfort or discomfort a pedestrian has in view of interactions with features of the environment. Physical trust is further described with respect to FIG. 8A.

In examples, an undisturbed motion attribute defines how a pedestrian behaves if motion of the pedestrian along a route is undisturbed. For example, a pedestrian will walk in a desired direction of motion at predetermined speed but for interruptions along a route, resulting in a driving force into the desired direction of motion 706. In examples, a pedestrian attribute defines the impact of other pedestrians on the motion of the pedestrian. In the example of FIG. 7A, the smart pedestrian 702 maintains a private sphere of personal space 712. When the other pedestrians 708A and 708B enter the sphere of personal space 712, a repulsive force occurs between the smart pedestrian 702 and the other pedestrians 708A and 708B. In examples, a structural attribute defines how smart pedestrians react to structures 704, such as buildings, walls, streets, obstacles, etc. The structures represent a repulsive force that pushes smart pedestrians to away from certain structures. In examples, the structure represents an attractive force that pulls pedestrians closer while moving along routes in a simulation. For example, during adverse weather conditions, a pedestrian travels along a route close to the structure for protection from the adverse weather conditions. A group attribute defines the attraction that occurs between a pedestrian and one or more pedestrians or objects. Pedestrians are attracted to other persons or objects at times while moving through an environment.

FIG. 7B is an illustration of pedestrians moving through an environment 720 subject to external forces. In the example of FIG. 7B, the environment is shown at a single frame of a scenario. In examples, the frame of data includes sensor data, vehicle dynamics data, and pedestrian dynamics data associated objects and features of the environment 720. In some embodiments, the sensor data, vehicle dynamics data, and pedestrian dynamics data associated with the environment are used to iteratively update the scenario at future timestamps. In this manner, the scenario is dynamic based on the responses of pedestrian dynamics models and vehicle dynamics models during simulations. For ease of explanation, particular forces are described in FIG. 7B. However, any force that impacts movement of a pedestrian due to the interpersonal or intrapersonal behaviors associated with a respective pedestrian can be modeled according to the present techniques.

In the example of FIG. 7B, a pedestrian 731 crosses the street onto sidewalk 768A. A pedestrian group 732 and a pedestrian group 734 are located on sidewalk 768A. additionally, a pedestrian 733 is located on the sidewalk 768A. A pedestrian group 735 crosses the street using crosswalk 760 in the direction of a ramp 762B where sidewalk 768B and sidewalk 768C meet. A pedestrian 736 is located on sidewalk 768B near the curb 764B. A pedestrian 737 walks along sidewalk 768C, and a pedestrian group 738 is located near the traffic light pole 772. The environment 720 also includes vehicles 742, 744, 746, 748, 750, and 752.

The vehicles 742, 744, 746, 748, 750, and 752 are located along a street including a crosswalk 760. A sidewalk 768A and sidewalk 768B are shown along the street including the crosswalk 760. Sidewalk 768A is connected to the street by curb 764A; sidewalk 768B is connected to the street by curb 764B. A sidewalk 768C is perpendicular to sidewalk 768B. As shown in the example of FIG. 7B, a ramp 762A enables ease of travel when moving across the sidewalk 768A to/from crosswalk 760. Similarly, a ramp 762B enables ease of travel when moving across the sidewalks 768B or 768C to/from crosswalk 760. Other features of the environment 720 includes a window sign 766, area lighting 770, traffic light 772, pedestrian signal 774, benches 776, trashcan 778, and awning 780.

In examples, the output of a pedestrian dynamics model for a respective pedestrian is based on, at least in part, the pedestrian's reaction to one or more categories of force in view of predetermined attributes. In examples, a force is an influence that can impact a trajectory of a pedestrian. For example, forces cause a pedestrian to change its velocity (e.g., to accelerate or decelerate) or heading. Forces can be counterbalanced by other forces or attributes associated with a respective pedestrian dynamics model.

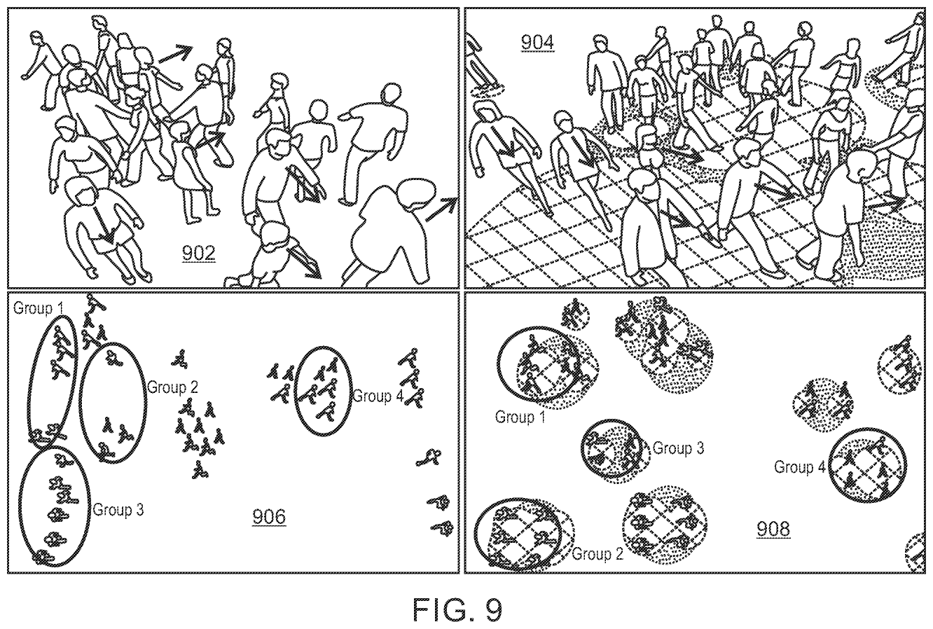

As shown in the example of FIG. 7B, pedestrian 731 jaywalks across the street toward sidewalk 768A. The sidewalk 768A represents an attractive force associated with pedestrian 731. The vehicle 746 changes lanes near the pedestrian 731 and represents A repulsive force associated with the pedestrian 731. Additionally, in the example of FIG. 7B, pedestrian group 732 is located alongside walk 768A. An attractive force is associated with members of the pedestrian group 732, where each respective pedestrian dynamics model includes attributes that describe how likely members of the pedestrian group are to stay near the group. FIG. 9 further describes forces between groups of pedestrians.

In the example of FIG. 7B, pedestrian 733 and pedestrian group 734 are located near a flashy attractive window sign 766 and pedestrian street signal 774. The window sign 766 and street signal 774 represent forces that impact pedestrians. The window sign 766 can be an attractive force to pedestrians, and pull pedestrians closer depending on their respective attributes. In examples, the pedestrian street signal 774 is an attractive force for pedestrians traveling along a route controlled by the pedestrian street signal 774, such as when the signal indicates pedestrians should stop. In examples, the pedestrian street signal 774 is a repulsive force for pedestrians traveling along a route controlled by the pedestrian street signal 774. For example, when pedestrians are stopped near the pedestrian street signal 774 and the pedestrian street signal 774 signals that pedestrians can “walk” or “go,” pedestrians near the pedestrian street signal 774 move away. In examples, pedestrians beyond a threshold distance from the pedestrian street signal 774 are attracted to the pedestrian street signal 774 signals when the signal indicates pedestrians can “walk” or “go.” In examples, depending on the time of day, weather conditions, or lighting conditions, the streetlight 770 can generate an attractive force that draws pedestrians to the light.

As shown in the example of FIG. 7B, the pedestrian group 735 includes a person and animal connected by a leash. Forces associated with the boundaries of crosswalk 760 are modeled as walls that encourage pedestrians to travel within the boundaries of the crosswalk. The reaction or behavior of a smart pedestrian to the forces associated with the boundaries of the crosswalk 760 is determined according to one or more attributes of the respective pedestrian dynamics model. In the example of FIG. 7B, pedestrian 736 is located near curb 764B. The curb 764B can be associated with an attractive force that draws pedestrians to the curb based on respective attributes. The pedestrian 737 is observed crossing the ramp 762B and continuing along sidewalk 768C. In examples, the ramp 762B represents an attractive force where pedestrians are drawn to the ramp from the sidewalks or crosswalks. In the example of FIG. 7B, the pedestrian group is shown near an awning 780. In examples, the awning 780 is an attractive force for pedestrians traveling along a route in adverse weather conditions. For example, when pedestrians are near the awning 780 pedestrians can walk or stop under the awing for protection.

The forces are modeled throughout the environment at each timestamp of the scenario, and a response for each pedestrian is determined at each timestamp of the scenario. For example, the response for each pedestrian is generated by iteratively updating a heading and a velocity of the pedestrian in view of the forces impacting the pedestrian. The forces are applied to the pedestrian dynamics model for the respective pedestrian, and outputs are generated. In the example of FIG. 7B, the social force model 700 also includes attributes responsive to forces representative of vehicle-pedestrian interactions. For example, the vehicle 742 is associated with forces that are largely based on the speed of the vehicle. The forces associated with vehicle-pedestrian interactions are based on, at least in part, proxemic utility. Proxemic utility refers to zones of interpersonal distance that characterize each pedestrian. In some embodiments, the present techniques model forces representative of vehicle-pedestrian interactions based on proxemic utility associated with a respective pedestrian. The proxemic utility is defined, at least in part, by the attributes of the respective pedestrian dynamics model.

FIG. 8A shows a plot 801 of zones of interpersonal distance. The x-axis represents time t 802, and the y-axis represents a distance d between the pedestrian and the vehicle. In the plot 801, a respective pedestrian represented by line 808 is associated with a pedestrian dynamics model that causes the respective pedestrian to exhibit behaviors during simulation in response to at least one force. The pedestrian travels along the length of a crosswalk 806, where the length of the crosswalk 806 is shown along the x-axis. In examples, the pedestrian associated with line 808 is the same as or similar to pedestrian group 735 of FIG. 7. In examples, the crosswalk 806 is the same as or similar to crosswalk 760 of FIG. 7. Line 808 represents the movement of the pedestrian across the crosswalk 806. The vehicle associated with line 810 approaches across the crosswalk 806, where the length of the crosswalk 806 spans the street traveled by the vehicle associated with line 810. In examples, the vehicle associated with line 810 is the same as or similar to vehicle 742 of FIG. 7. Line 810 represents the movement of the vehicle across (e.g., perpendicular to) the crosswalk 806.

In the example of FIG. 8A, a physical trust attribute associated with each respective pedestrian partitions a set of possible states (e.g., physical locations) of the world during simulated vehicle-pedestrian interactions into three subspaces. In the conflict zone 816, a vehicle-pedestrian collision will happen and there is nothing either the vehicle or pedestrian can do to prevent it. In the trust zone 814, the vehicle-pedestrian collision may occur, however the vehicle or pedestrian can act to prevent it. In the escape zone 812, the vehicle-pedestrian collision may happen but the pedestrian can act to prevent it, without needing to trust the vehicle. As the distance d between the pedestrian 808 and vehicle 810 decreases, the physical trust attributes associated with the pedestrian 808 transitions from the escape zone 812, to the trust zone 814, and to the crash zone 816. A response of a pedestrian during simulation changes depending on if the pedestrian is located in the escape zone 812, the trust zone 814, or the crash zone 816.

In the example of plot 801 in FIG. 8A, the vehicle 810 is assumed to be on approach to a crosswalk 806 where the pedestrian 808 is located. However, a pedestrian can interact with the front, back, or lateral areas of the vehicle. The locations of the escape zone 812, trust zone 814, and crash zone 816 are based on a heading and velocity of the vehicle with respect to the pedestrian. In examples, when the vehicle 810 moves with a low speed, forces caused by the vehicle vary based on the position of the smart pedestrian with respect to the vehicle. When moving forward, a head of the vehicle is associated with a zone of influence. As vehicle velocity (e.g., longitudinal velocity) increases, a longer zone of influence is created in front of vehicle. In the escape zone 812, the pedestrian is most comfortable at the head of the vehicle since the distance between the pedestrian and vehicle appears to provide enough space for the pedestrian to escape, based on the velocity of the vehicle. In the trust zone 814, the pedestrian at the head of the vehicle shows trust in the vehicle, since the distance between the pedestrian and vehicle may not provide enough space for the pedestrian to avoid conflict with the vehicle, based on the velocity of the vehicle. In the conflict zone 816, the pedestrian at the head of the vehicle anticipates a conflict with the vehicle based on the velocity of the vehicle, since the distance between the pedestrian and vehicle may not provide enough space for the pedestrian to avoid conflict with the vehicle.

In the example of FIG. 8A, plot 821 shows varying zones based on a velocity of a vehicle. Velocity of the vehicle is shown along the x-axis 822, and distance is shown along the y-axis 824. In examples, the vehicle is the same as or similar to vehicle 810. The escape zone 826, trust zone 828, and conflict zone 830 are shown as a function of the vehicle velocity and distance to the pedestrian. In examples, when a vehicle approaches a pedestrian, the vehicle causes a repulsive force that impacts a smart pedestrian, where the repulsive force increases as a velocity of the vehicle increases. In a scenario where the vehicle and pedestrian come into near contact, the repulsive force produced by the vehicle shifts to a direction that is perpendicular to the car's direction of motion, so that pedestrians slide out of the vehicle's path rather than being pushed off course by the vehicle.

FIG. 8B shows proactive metrics associated with safety assessment of simulations including pedestrian dynamics models based on social force models. In examples, the system under assessment is an autonomous system, such as the autonomous system 604 of FIG. 6. In the example of FIG. 8B, the vehicle shown includes an autonomous system, and assessment of the vehicle or vehicle metrics refer to assessment of the autonomous system. In examples, the vehicle metrics for assessment are based on a zone of influence as shown at reference number 830. The pedestrian metrics for assessment are based on pedestrian zones as shown at reference number 840. Proactive vehicle movement is achieved by defining a zone of influence as a 180-degree zone in the same orientation as the vehicle. The radius of the zone of influence is proportional to the linear velocity of the vehicle, resulting in a larger influence margin at higher velocities. In examples, the zone of influence defines an area where vehicle-pedestrian interactions occur.

In FIG. 8B, the vehicle's zone of influence is shown at varying velocities where α∈R₊. At reference numbers 832, 834, 836, and 838, the zone of influence associated with the vehicle varies according to the respective velocity and orientation/heading of the vehicle. Similarly, pedestrian zones shown at reference 840 include a personal zone 846 and a cooperation zone 848. The personal zone 846 is defined by a personal zone radius 844. The cooperation zone 848 is defined by a cooperation zone radius 842. In examples, the personal zone 846 is a space around the pedestrian where any intrusion causes discomfort. In examples, the cooperation zone 848 is a space around the pedestrian where cooperation between the vehicle and pedestrian is possible, without discomfort. For ease of illustration, the zones as described herein as shown with particular shapes, however any shape can be used according to the present techniques.

As the pedestrian tends to clear the personal zone from human intrusion, (s)he tends to clear the cooperation zone of any vehicle intrusion.

In examples, safety is assessed based on, at least in part, an average number of personal zone and cooperation zone infringements made by the simulated autonomous system at various speeds in a given scenario. For example, a safety index is determined within a zone of influence to ensure the safety of pedestrians while invoking more cooperative pedestrian behavior. The pedestrian zones are used to evaluate the security index. In examples, infringing upon (e.g., entering) the personal zone of a pedestrian is failed navigation; entering a cooperation zone with SI<1 is possible pedestrian discomfort. Larger SI values equal better navigation. In examples, the safety index is calculated as follows:

$${SI}_{j} ( t ) = \frac{{D}_{j} ( t ) - {R}_{S}}{{R}_{C} - {R}_{S}}$$

Where Dⱼ a minimum distance between a pedestrian j and vehicle body; R_{S} radius of personal zone; and R_{C} radius of cooperation zone. In this manner, the present techniques enable simulation and assessment of scenarios that include contact and close contact between vehicles and pedestrians. In examples, an autonomous system is trained, updated, modified, or developed based on the results of the simulation.

FIG. 9 shows a simulation of smart pedestrians according in view of groups or other pedestrians. In examples, the smart pedestrians shown in FIG. 9 adjust a respective path and/or velocity in view of social force parameters based on the proximity of other objects, traffic infrastructure/signals/signs, structures, weather conditions, time of day, terrain, landscape, or any combinations thereof. In some embodiments, a simulation infrastructure (e.g., simulation infrastructure 600 of FIG. 6) enables a user to assign social force models with predetermined parameters as a pedestrian behavior. The parameters include, for example, pedestrian groups, pedestrian types, pedestrian impairments, and the like. At reference number 902, single pedestrians are shown in an environment moving in random directions. In the example at reference number 902, no pedestrian groups are present. This may occur, for example, when simulating pedestrians traveling to work. Pedestrians tend to walk alone when headed towards office locations during morning rush hour. Pedestrians also tend to walk alone when headed away from office locations during morning rush hour. At reference number 904, a dense group of single pedestrians are shown in an environment moving in substantially the same direction. In the example at reference number 904, no pedestrian groups are present. This may occur, for example, in large crowds headed to an upcoming event, such as a concert, sporting event, or other attraction.

At reference number 906, groups of pedestrians are shown in an environment moving in a same direction. In the example at reference number 906, the pedestrian groups take up more physical space. At reference number 908, groups of pedestrians are shown in an environment moving in varying directions. In the example at reference number 908, the pedestrian groups consume less physical space when compared to the pedestrian groups at reference number 906. In some embodiments, attributes of each respective pedestrian of the pedestrian groups is determined by a respective pedestrian dynamics model.

In examples, multiple pedestrians exhibit more confident behavior when interacting with a vehicle when compared to an individual pedestrian. When specifying a scenario for simulation pedestrians can, for example, be assigned a classification to form pedestrian groups. In examples, the classification is used to determine an attractive force toward other pedestrians with the same class. For example, the pedestrian classes include pedestrian groups such as couples (e.g., group of 2); friends (e.g., group of greater than or equal to 2); families (e.g., group of greater than or equal to 2); and coworkers (e.g., group of greater than or equal to 2). In examples, the pedestrians as assigned a pedestrian type (e.g., adult, child, elder), a pedestrian purpose (e.g., work, leisure), or a pedestrian impairment, disability, or handicap status. In examples, the pedestrian classification, pedestrian type, pedestrian purpose, pedestrian impairment, or any combinations thereof, are assigned to each respective pedestrian based on test objectives, including the autonomous system behavior under test. Additionally, in examples, the pedestrian classification, pedestrian type, pedestrian purpose, pedestrian impairment, or any combinations thereof are assigned to achieve a distribution of agents across classes.

In some embodiments, vision attributes associated with each respective pedestrian are defined in the pedestrian dynamics model by specifying a visual angle and distance associated with the simulated pedestrians. In examples, the vision attribute governs how smart pedestrians perceive an autonomous vehicle and other pedestrians during a simulation. Pedestrians react to the vehicle by adjusting their velocity and/or travel direction based on the time-to-conflict between the pedestrian and the vehicle and the agent's danger and risk radius (i.e., personal and cooperation zones). For example, pedestrians stop, slow down, speed up, and step back (i.e., travel backwards) in response to the vehicle. The time-to-conflict, danger radius, and risk radius parameters are adjustable attributes of the social force model. In examples, when the vehicle has the same speed as the pedestrian, the simulated pedestrian behaves as if the vehicle is a pedestrian (i.e., zones match human-human interaction interpersonal distances). In some embodiments, pedestrian behavior is defined to comply/ignore traffic signals at light. Additionally, in embodiments, the pedestrian's velocity and starting/ending pose is defined manually prior to simulation.

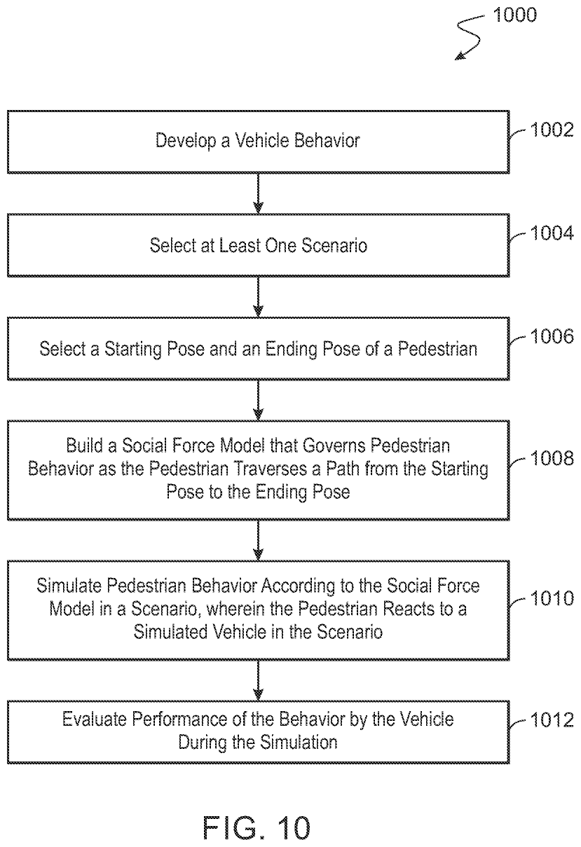

Referring now to FIG. 10, illustrated is a flowchart of a first process 1000 for simulated smart pedestrians. In some embodiments, one or more of the steps described with respect to process 1000 are performed (e.g., completely, partially, and/or the like) by the simulation infrastructure 600 of FIG. 6. Additionally, or alternatively, in some embodiments one or more steps described with respect to process 600 are performed (e.g., completely, partially, and/or the like) by another device or group of devices separate from or including simulation infrastructure 600 such as device 300 of FIG. 3.

At block 1002, a vehicle behavior is developed, where the vehicle behavior is a function or capability the vehicle (e.g., an autonomous vehicle) is expected to perform. In examples, the vehicle is expected to perform the behavior while ensuring the safety of pedestrians.

At block 1004, at least one scenario is selected. In examples, the at least one scenario is selected or specified so that during a simulation of the scenario (e.g., simulation of the scenario during testing, validation, or verification of the AV) the vehicle should exhibit the developed behavior.

At block 1006, a starting pose and an ending pose of a pedestrian is selected.

At block 1008, a social force model is built that governs pedestrian behavior as the pedestrian traverses a path from the starting pose to the ending pose.

At block 1010, pedestrian behavior is simulated according to the social force model in the at least one scenario, wherein the pedestrian reacts to a simulated vehicle in the scenario. For example, the pedestrian velocity and/or travel direction is adjusted based on the social force model. The social force model includes pedestrian attributes adjustable parameters of the based on the time-to-conflict between the pedestrian and the vehicle and the pedestrian's danger and risk radius (i.e., personal and cooperation zones)). In examples, the data associated with a smart pedestrian varies in response to features of the simulated environment by a velocity, acceleration, or heading of the pedestrian changing to reflect a reaction (e.g., change in behavior) of the pedestrian to the feature.

At block 1012, performance of the behavior by the vehicle during the simulation is evaluated. In some embodiments, the performance of the behavior is compared to an expected behavior or a known standard to determine if the performance of the behavior by the vehicle is satisfactory. Additionally, in some embodiments, the performance of the behavior by the vehicle during the simulation is iteratively evaluated and refined until the performance is satisfactory. For example, the vehicle behavior is refined, updated, and evaluated in view of scenarios including smart pedestrians until the performance of the behavior is satisfactory.

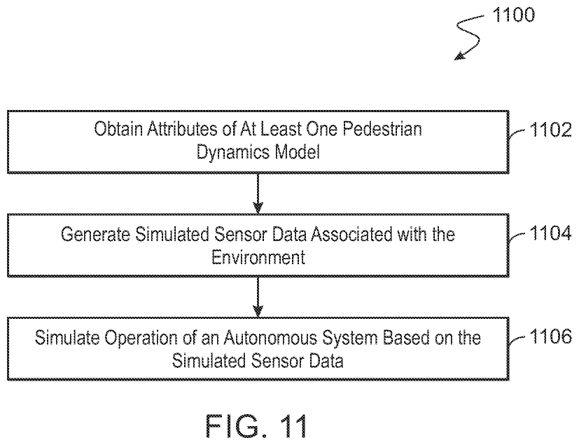

Referring now to FIG. 11, illustrated is a flowchart of a second process 1100 for simulated smart pedestrians. In some embodiments, one or more of the steps described with respect to process 1100 are performed (e.g., completely, partially, and/or the like) by the simulation infrastructure 600 of FIG. 6. Additionally, or alternatively, in some embodiments one or more steps described with respect to process 600 are performed (e.g., completely, partially, and/or the like) by another device or group of devices separate from or including simulation infrastructure 600 such as device 300 of FIG. 3.

At block 1102, attributes of at least one pedestrian dynamics model are specified. In some embodiments, the at least one pedestrian dynamics model is a social force model. In a social force model, the attributes describe pedestrian behavior responsive to external forces in the environment. The attributes govern behavior of a respective pedestrian in response to features of an environment. In examples, the at least one pedestrian dynamics model outputs a heading and a velocity associated with a respective pedestrian at each timestamp of a scenario.

At block 1104, simulated sensor data associated with the environment is generated. The simulated sensor data comprises aggregated data from at least one sensor model, at least one vehicle dynamics model, and the at least one pedestrian dynamics model.

At block 1106, operation of an autonomous system in the environment is simulated based on the simulated sensor data associated with the environment. Vehicle-pedestrian interactions are modeled by the at least one pedestrian dynamics model as external forces in the environment impacting behavior of the respective pedestrian. In examples, the vehicle-pedestrian interactions are defined according to proxemic utility. Additionally, in examples, the at least one vehicle dynamics model, and the at least one pedestrian dynamics model iteratively execute during simulation to generate simulated sensor data. In examples, the at least one vehicle dynamics model, and the at least one pedestrian dynamics model iteratively execute during simulation to generate simulated sensor data responsive to the output of the autonomous system.

In some embodiments, the output or response of an autonomous system during simulation is evaluated within a zone of influence. In examples, the zone of influence varies based on a velocity associated with an autonomous system during simulation. A safety index associated with the autonomous system is based on, at least in part, an average number of personal zone and cooperation zone infringements made by the simulated autonomous system at various speeds in a given scenario. In examples, entering the personal zone of a pedestrian represents a failure to achieve safe operation. The present techniques enable scenarios that include conflicts and near conflicts between vehicles and pedestrians. Including realistic pedestrian behavior in scenarios for simulation improves the quality of information learned from the simulation. Robust autonomous systems are further developed and/or tested based on this quality information.

### CLAUSES

According to some non-limiting embodiments or examples, provided is a method, comprising: obtaining, with at least one processor, attributes of at least one pedestrian dynamics model, wherein the attributes govern behavior of a simulated pedestrian in response to features of an environment; generating, with the at least one processor, simulated sensor data associated with the environment, wherein the simulated sensor data comprises aggregated data from at least one sensor model, at least one vehicle dynamics model, and the at least one pedestrian dynamics model; and simulating, with the at least one processor, operation of an autonomous vehicle in the environment based on the simulated sensor data, wherein vehicle-pedestrian interactions are modeled by the at least one pedestrian dynamics model as external forces in the environment impacting behavior of the simulated pedestrian.

According to some non-limiting embodiments or examples, provided is a system comprising at least one processor, and at least one non-transitory storage media storing instructions that, when executed by the at least one processor, cause the at least one processor to: obtain attributes of at least one pedestrian dynamics model, wherein the attributes govern behavior of a simulated pedestrian in response to features of an environment; generate simulated sensor data associated with the environment, wherein the simulated sensor data comprises aggregated data from at least one sensor model, at least one vehicle dynamics model, and the at least one pedestrian dynamics model; and simulate operation of an autonomous vehicle in the environment based on the simulated sensor data, wherein vehicle-pedestrian interactions are modeled by the at least one pedestrian dynamics model as external forces in the environment impacting behavior of the simulated pedestrian.

According to some non-limiting embodiments or examples, provided is at least one non-transitory computer-readable medium comprising one or more instructions that, when executed by at least one processor, cause the at least one processor to: obtain attributes of at least one pedestrian dynamics model, wherein the attributes govern behavior of a simulated pedestrian in response to features of an environment; generate simulated sensor data associated with the environment, wherein the simulated sensor data comprises aggregated data from at least one sensor model, at least one vehicle dynamics model, and the at least one pedestrian dynamics model; and simulate operation of an autonomous vehicle in the environment based on the simulated sensor data, wherein vehicle-pedestrian interactions are modeled by the at least one pedestrian dynamics model as external forces in the environment impacting behavior of the simulated pedestrian.

Further non-limiting aspects or embodiments are set forth in the following numbered clauses:

Clause 1: A method, comprising: obtaining, with at least one processor, attributes of at least one pedestrian dynamics model, wherein the attributes govern behavior of a simulated pedestrian in response to features of an environment; generating, with the at least one processor, simulated sensor data associated with the environment, wherein the simulated sensor data comprises aggregated data from at least one sensor model, at least one vehicle dynamics model, and the at least one pedestrian dynamics model; and simulating, with the at least one processor, operation of an autonomous vehicle in the environment based on the simulated sensor data, wherein vehicle-pedestrian interactions are modeled by the at least one pedestrian dynamics model as external forces in the environment impacting behavior of the simulated pedestrian.

Clause 2: The method of clause 1, wherein the at least one sensor model, the at least one vehicle dynamics model, and the at least one pedestrian dynamics model iteratively execute to generate simulated sensor data associated with the environment during a simulation.

Clause 3: The method of clauses 1 or 2, wherein the at least one sensor model, the at least one vehicle dynamics model, and the at least one pedestrian dynamics model iteratively execute responsive to output of the autonomous vehicle during simulation.

Clause 4: The method of any one of clauses 1-3, wherein the at least one pedestrian dynamics model comprises a social force model.

Clause 5: The method of any one of clauses 1-4, wherein the attributes describe pedestrian behavior responsive to the external forces in the environment.

Clause 6: The method of any one of clauses 1-5, wherein the at least one pedestrian dynamics model outputs a heading and a velocity associated with the simulated pedestrian at each timestamp of a scenario during a simulation.

Clause 7: The method of any one of clauses 1-6, wherein the vehicle-pedestrian interactions are defined according to proxemic utility.

Clause 8: The method of any one of clauses 1-7, comprising evaluating a response of the autonomous vehicle to the simulated sensor data within a zone of influence for evaluation as an area where vehicle-pedestrian interactions occur.

Clause 9: A system, comprising: at least one processor, and at least one non-transitory storage media storing instructions that, when executed by the at least one processor, cause the at least one processor to: obtain attributes of at least one pedestrian dynamics model, wherein the attributes govern behavior of a simulated pedestrian in response to features of an environment; generate simulated sensor data associated with the environment, wherein the simulated sensor data comprises aggregated data from at least one sensor model, at least one vehicle dynamics model, and the at least one pedestrian dynamics model; and simulate operation of an autonomous vehicle in the environment based on the simulated sensor data, wherein vehicle-pedestrian interactions are modeled by the at least one pedestrian dynamics model as external forces in the environment impacting behavior of the simulated pedestrian.

Clause 10: The system of clause 9, wherein the at least one sensor model, the at least one vehicle dynamics model, and the at least one pedestrian dynamics model iteratively execute to generate simulated sensor data associated with the environment during a simulation.

Clause 11: The system of clauses 9 or 10, wherein the at least one sensor model, the at least one vehicle dynamics model, and the at least one pedestrian dynamics model iteratively execute responsive to output of the autonomous vehicle during simulation.

Clause 12: The system of any one of clauses 9-11, wherein the at least one pedestrian dynamics model comprises a social force model.

Clause 13: The system of any one of clauses 9-12, wherein the attributes describe pedestrian behavior responsive to the external forces in the environment.

Clause 14: The system of any one of clauses 9-13, wherein the at least one pedestrian dynamics model outputs a heading and a velocity associated with the simulated pedestrian at each timestamp of a scenario during a simulation.

Clause 15: The system of any one of clauses 9-14, wherein the vehicle-pedestrian interactions are defined according to proxemic utility.

Clause 16: At least one non-transitory storage media storing instructions that, when executed by at least one processor, cause the at least one processor to: obtain attributes of at least one pedestrian dynamics model, wherein the attributes govern behavior of a simulated pedestrian in response to features of an environment; generate simulated sensor data associated with the environment, wherein the simulated sensor data comprises aggregated data from at least one sensor model, at least one vehicle dynamics model, and the at least one pedestrian dynamics model; and simulate operation of an autonomous vehicle in the environment based on the simulated sensor data, wherein vehicle-pedestrian interactions are modeled by the at least one pedestrian dynamics model as external forces in the environment impacting behavior of the simulated pedestrian.

Clause 17: The least one non-transitory storage media of clause 16, wherein the at least one sensor model, the at least one vehicle dynamics model, and the at least one pedestrian dynamics model iteratively execute to generate simulated sensor data associated with the environment during a simulation.

Clause 18: The least one non-transitory storage media of clauses 16 or 17, wherein the at least one sensor model, the at least one vehicle dynamics model, and the at least one pedestrian dynamics model iteratively execute responsive to output of the autonomous vehicle during simulation.

Clause 19: The least one non-transitory storage media of any one of clauses 16-18, wherein the at least one pedestrian dynamics model comprises a social force model.

Clause 20: The least one non-transitory storage media of any one of clauses 16-19, wherein the vehicle-pedestrian interactions are defined according to proxemic utility.

In the foregoing description, aspects and embodiments of the present disclosure have been described with reference to numerous specific details that can vary from implementation to implementation. Accordingly, the description and drawings are to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction. Any definitions expressly set forth herein for terms contained in such claims shall govern the meaning of such terms as used in the claims. In addition, when we use the term “further comprising,” in the foregoing description or following claims, what follows this phrase can be an additional step or entity, or a sub-step/sub-entity of a previously recited step or entity.

What is claimed is:

1. A method, comprising:
obtaining, with at least one processor, attributes of at least one pedestrian dynamics model, wherein the attributes govern behavior of a simulated pedestrian in response to features of an environment;
generating, with the at least one processor, simulated sensor data associated with the environment, wherein the simulated sensor data comprises aggregated data from at least one sensor model, at least one vehicle dynamics model, and the at least one pedestrian dynamics model; and
simulating, with the at least one processor, operation of an autonomous vehicle in the environment based on the simulated sensor data, wherein vehicle-pedestrian interactions are modeled by the at least one pedestrian dynamics model as external forces in the environment impacting behavior of the simulated pedestrian.

2. The method of claim 1, wherein the at least one sensor model, the at least one vehicle dynamics model, and the at least one pedestrian dynamics model iteratively execute to generate simulated sensor data associated with the environment during a simulation.

3. The method of claims 1 or 2, wherein the at least one sensor model, the at least one vehicle dynamics model, and the at least one pedestrian dynamics model iteratively execute responsive to output of the autonomous vehicle during simulation.

4. The method of any one of claims 1-3, wherein the at least one pedestrian dynamics model comprises a social force model.

5. The method of any one of claims 1-4, wherein the attributes describe pedestrian behavior responsive to the external forces in the environment.

6. The method of any one of claims 1-5, wherein the at least one pedestrian dynamics model outputs a heading and a velocity associated with the simulated pedestrian at each timestamp of a scenario during a simulation.

7. The method of any one of claims 1-6, wherein the vehicle-pedestrian interactions are defined according to proxemic utility.

8. The method of any one of claims 1-7, comprising evaluating a response of the autonomous vehicle to the simulated sensor data within a zone of influence for evaluation as an area where vehicle-pedestrian interactions occur.

9. A system, comprising:
at least one processor, and
at least one non-transitory storage media storing instructions that, when executed by the at least one processor, cause the at least one processor to:
obtain attributes of at least one pedestrian dynamics model, wherein the attributes that govern behavior of a simulated pedestrian in response to features of an environment;
generate simulated sensor data associated with the environment, wherein the simulated sensor data comprises aggregated data from at least one sensor model, at least one vehicle dynamics model, and the at least one pedestrian dynamics model; and
simulate operation of an autonomous vehicle in the environment based on the simulated sensor data, wherein vehicle-pedestrian interactions are modeled by the at least one pedestrian dynamics model as external forces in the environment impacting behavior of the simulated pedestrian.

10. The system of claim 9, wherein the at least one sensor model, the at least one vehicle dynamics model, and the at least one pedestrian dynamics model iteratively execute to generate simulated sensor data associated with the environment during a simulation.

11. The system of claims 9 or 10, wherein the at least one sensor model, the at least one vehicle dynamics model, and the at least one pedestrian dynamics model iteratively execute responsive to output of the autonomous vehicle during simulation.

12. The system of any one of claims 9-11, wherein the at least one pedestrian dynamics model comprises a social force model.

13. The system of any one of claims 9-12, wherein the attributes describe pedestrian behavior responsive to the external forces in the environment.

14. The system of any one of claims 9-13, wherein the at least one pedestrian dynamics model outputs a heading and a velocity associated with the simulated pedestrian at each timestamp of a scenario during a simulation.

15. The system of any one of claims 9-14, wherein the vehicle-pedestrian interactions are defined according to proxemic utility.

16. At least one non-transitory storage media storing instructions that, when executed by at least one processor, cause the at least one processor to:
obtain attributes of at least one pedestrian dynamics model, wherein the attributes that govern behavior of a simulated pedestrian in response to features of an environment;
generate simulated sensor data associated with the environment, wherein the simulated sensor data comprises aggregated data from at least one sensor model, at least one vehicle dynamics model, and the at least one pedestrian dynamics model; and
simulate operation of an autonomous vehicle in the environment based on the simulated sensor data, wherein vehicle-pedestrian interactions are modeled by the at least one pedestrian dynamics model as external forces in the environment impacting behavior of the simulated pedestrian.

17. The least one non-transitory storage media of claim 16, wherein the at least one sensor model, the at least one vehicle dynamics model, and the at least one pedestrian dynamics model iteratively execute to generate simulated sensor data associated with the environment during a simulation.

18. The least one non-transitory storage media of claims 16 or 17, wherein the at least one sensor model, the at least one vehicle dynamics model, and the at least one pedestrian dynamics model iteratively execute responsive to output of the autonomous vehicle during simulation.

19. The least one non-transitory storage media of any one of claims 16-18, wherein the at least one pedestrian dynamics model comprises a social force model.

20. The least one non-transitory storage media of any one of claims 16-19, wherein the vehicle-pedestrian interactions are defined according to proxemic utility.
